(19) United States
(12) Patent Application Publication
(10) Pub. No.: US 2025/0151481 A1
(43) Pub. Date: May 8, 2025

(54) SHAPE-ADAPTIVE DISPLAY ASSEMBLY

(71) Applicant: Google LLC, Mountain View, CA (US)

(72) Inventor: Jürgen Burggraf, Schaerding (AT)

(21) Appl. No.: 18/932,320

(22) Filed: Oct. 30, 2024

Related U.S. Application Data
(60) Provisional application No. 63/595,950, filed on Nov. 3, 2023.

(51) Int. Cl. H01L 33/54; G04G 9/10; H01L 25/075; H01L 33/00; H01L 33/62

(52) U.S. Cl. CPC H10H 20/853; H01L 25/0753; H10H 20/018; H10H 20/857; G04G 9/10; H10H 20/0362; H10H 20/0364

(57) ABSTRACT

Shape-adaptive display assemblies are described herein, along with methods for their fabrication. One example method for fabricating a display assembly with a rigid segment and a flexible segment includes: depositing a pattern of conductive material onto a first substrate; coupling an integrated circuit to a first side of the pattern of conductive material, the integrated circuit disposed on the rigid segment without extending to the flexible segment; depositing a molding layer onto the first side of the pattern of conductive material, the molding layer configured to encapsulate the integrated circuit and to extend over the rigid segment and the flexible segment; bonding a second substrate to the molding layer and removing the first substrate to expose a second side of the pattern of conductive material; and coupling a plurality of pixel emitters to the second side of the pattern of conductive material and removing the second substrate.

### CROSS-REFERENCE TO RELATED APPLICATION

This application claims priority to U.S. Provisional Patent Application No. 63/595,950, filed on Nov. 3, 2023, the disclosure of which is incorporated by reference herein in its entirety.

### BACKGROUND

Digitally-encoded images may be presented to viewers using a variety of different types of image displays featured in a variety of different types of devices. For example, personal computing devices (e.g., laptops, tablets, etc.), mobile devices (e.g., smartphones, electronic readers, etc.), wearable devices (e.g., smartwatches, etc.), extended reality devices (e.g., virtual and augmented reality headsets), televisions, appliances, vehicles, and various other devices and products all may feature image displays configured to present images to users. These devices vary in many ways, including their shape, size, power sensitivity, typical use case, price range, and so forth. Accordingly, the requirements and characteristics desired for display assemblies built into different devices may similarly vary along various dimensions.

### SUMMARY

One characteristic that may be desirable for certain display assemblies configured for use in certain devices is an ability to bend and flex to adapt the shape of their profile to conform to an enclosure in which they may be integrated. Shape-adaptive display assemblies exhibiting this type of flexibility and methods for fabricating or constructing them are described herein. As described herein, a printed circuit pattern and various electronic components (e.g., including one or more integrated circuits) may be supported on rigid substrates that can provide planar surfaces and suitable structural support during a fabrication process. Later, however, these rigid substrates may be removed to allow at least some segments of the finished display assembly to be shape adaptive (i.e., free to bend, flex, curve, etc.). Pixel emitters such as micro light emitting diodes (microLEDs) transferred to the display assembly from a donor wafer may be distributed to both rigid and flexible segments of the display assembly, and one or more integrated circuits may be configured to perform backplane functions to drive and control light emissions of these pixel emitters. Various methods and techniques described herein may be performed to fabricate these shape-adaptive display assemblies in accordance with principles detailed below.

One example implementation described herein involves a display assembly that may be fabricated using a method such as that described above. For example, the display assembly may include: 1) a rigid segment configured to maintain a planar profile shape and a flexible segment configured to allow for an adaptable profile shape; 2) a pattern of conductive material extending over the rigid segment and the flexible segment; 3) an integrated circuit disposed on the rigid segment without extending to the flexible segment, the integrated circuit coupled to a first side of the pattern of conductive material; 4) a molding layer extending over the rigid segment and the flexible segment, the molding layer deposited on the first side of the pattern of conductive material and encapsulating the integrated circuit; and 5) a plurality of pixel emitters coupled to a second side of the pattern of conductive material opposite the first side of the pattern of conductive material.

Another example implementation described herein involves a device that includes, among other components, a display assembly such as described above. For example, the device may include: 1) a memory storing instructions; 2) a processor communicatively coupled to the memory and configured to execute the instructions to present image content; and 3) a display assembly having a rigid segment with a planar profile shape and a flexible segment with a non-planar profile shape. Similarly as described above, the display assembly may include: 1) a pattern of conductive material extending over the rigid segment and the flexible segment; 2) an integrated circuit disposed on the rigid segment without extending to the flexible segment, the integrated circuit coupled to a first side of the pattern of conductive material; 3) a molding layer extending over the rigid segment and the flexible segment, the molding layer deposited on the first side of the pattern of conductive material and encapsulating the integrated circuit; and 4) a plurality of pixel emitters coupled to a second side of the pattern of conductive material opposite the first side of the pattern of conductive material, the plurality of pixel emitters being configured to display the image content presented by the processor.

Yet another example implementation described herein, for instance, involves a method for fabricating a display assembly having a rigid segment and a flexible segment. The method includes: 1) depositing a pattern of conductive material onto a first substrate; 2) coupling an integrated circuit to a first side of the pattern of conductive material, the integrated circuit disposed on the rigid segment without extending to the flexible segment; 3) depositing a molding layer onto the first side of the pattern of conductive material, the molding layer configured to encapsulate the integrated circuit and to extend over the rigid segment and the flexible segment; 4) bonding a second substrate to the molding layer and removing the first substrate to expose a second side of the pattern of conductive material opposite the first side of the pattern of conductive material; and 5) coupling a plurality of pixel emitters to the second side of the pattern of conductive material and removing the second substrate.

Yet another example implementation described herein involves a display fabrication system fabricating a shape-adaptive display assembly. The display fabrication system may include, for instance: a memory storing instructions and a processor communicatively coupled to the memory and configured to execute the instructions to cause the display fabrication system to fabricate a display assembly by performing a process. The process performed by the display fabrication system to fabricate the display assembly may include: 1) depositing a pattern of conductive material onto a first substrate; 2) coupling an integrated circuit to a first side of the pattern of conductive material, the integrated circuit disposed on a rigid segment of the display assembly without extending to a flexible segment of the display assembly; 3) depositing a molding layer onto the first side of the pattern of conductive material, the molding layer configured to encapsulate the integrated circuit and to extend over the rigid segment and the flexible segment; 4) bonding a second substrate to the molding layer and removing the first substrate to expose a second side of the pattern of conductive material opposite the first side of the pattern of conductive material; and 5) coupling a plurality of pixel emitters to the second side of the pattern of conductive material and removing the second substrate.

Various additional operations may be added to these processes and methods as may serve a particular implementation, examples of which will be described in more detail below. Additionally, it will be understood that each of the processes and operations described as being performed by different types of implementations in the examples above may additionally or alternatively be performed by other types of implementations as well.

The details of these and other implementations are set forth in the accompanying drawings and the description below. Other features will also be made apparent from the following description, drawings, and claims.

### BRIEF DESCRIPTION OF THE DRAWINGS

FIG. 1 shows illustrative aspects of an example implementation of a shape adaptive display assembly in accordance with principles described herein.

FIG. 2 shows an illustrative method for fabricating a shape-adaptive display assembly in accordance with principles described herein.

FIG. 3 shows an illustrative device that includes, among other components, a shape-adaptive display assembly in accordance with principles described herein.

FIG. 4 shows illustrative aspects of a smartwatch device serving as a particular example of the device of FIG. 3 in accordance with principles described herein.

FIGS. 5A-5K show illustrative aspects of fabricating a shape-adaptive display assembly in various stages in accordance with principles described herein.

FIG. 6 shows illustrative aspects of transferring a set of pixel emitters to a carrier substrate after fabrication of the set of pixel emitters in accordance with principles described herein.

FIG. 7 shows illustrative display tiles within a display assembly and certain aspects relating to a driver circuit that corresponds to one of the display tiles in accordance with principles described herein.

FIGS. 8A-8B show illustrative aspects of fabricating a shape-adaptive display assembly that includes additional integrated circuits in accordance with principles described herein.

FIGS. 9A-9B show illustrative aspects of fabricating a shape-adaptive display assembly that includes passive interposer circuits in accordance with principles described herein.

FIGS. 10A-10B show illustrative aspects of fabricating a shape-adaptive display assembly that integrates sensors in accordance with principles described herein.

FIG. 11 shows illustrative aspects of a composite display assembly that includes a plurality of portions each implemented as a shape-adaptive display assembly in accordance with principles described herein.

FIG. 12 shows an illustrative computing system that may be used to implement various devices and/or systems in accordance with principles described herein.

### DETAILED DESCRIPTION

Shape-adaptive display assemblies are described herein. Along with brightness, power-efficiency, color accuracy, cost, size, and other considerations, shape adaptability can be an important and desirable characteristic for display assemblies used in certain devices and use cases. For example, for the display of a portable device such as a smartwatch or handheld mobile device (e.g., a smartphone, tablet, etc.), it may be desirable to have a flat, rigid segment for the main portion of the display while having other segments of the display capable of wrapping onto one or more sides of the device (e.g., to avoid having a bezel, to present extended content or separate content on the sides of the device, etc.). As another example, certain display panels may be integrated with curved surfaces, such as on an appliance, a car dashboard, or the like. In any of these or a variety of other situations, shape-adaptive display assemblies described herein may be used to provide many desirable display qualities (e.g., the brightness, resolution, and power efficiency of microLEDs) while bending and flexing to fit a variety of profiles that may be called for by different devices.

A first technical problem that is to be addressed to create a shape-adaptive display assembly is that pixel emitters and the backplane circuitry with which they are generally integrated are fabricated on rigid substrates using conventional lithographic fabrication processes (e.g., silicon wafers, etc.). Anything fabricated on such a substrate would generally not have much ability to bend or flex without snapping, stressing or breaking electrical contacts, and/or otherwise being damaged.

A technical solution described herein to this technical problem involves condensing the logical and electrical backplane circuitry for driving the pixel emitters onto a relatively small integrated circuit (referred to herein as a backplane circuit) and placing that circuit within a flexible carrier hosting a distribution of pixel emitters that are driven by the backplane circuit but that are placed beyond the edges of the backplane circuit. Even if the backplane circuit itself is rigid, the rest of the display assembly may be flexible (i.e., shape adaptive) so as to be well-adapted for use in the types of applications described above. Depending on the type and number of pixel emitters used for a given display assembly, however, other technical problems may arise, as will now be described.

Display assemblies featuring pixel emitters such as micro light emitting diodes (microLEDs) offer significant advantages compared to other display technologies (e.g., OLED, LCD). For example, each pixel emitter (e.g., each individual microLED or each cluster of red, green, and blue microLEDs) may be controllable to emit light (ON) or not emit light (OFF), leading to extremely high (e.g., infinite) contrast ratios. Moreover, response times of microLED pixels may be very short, leading to crisp and responsive displays with bright colors, high frame rates, and high power efficiency. To gain these and other significant benefits of microLEDs on a direct-view display, however, a technical problem may arise relating to how power and signaling can be distributed from the backplane circuit to the pixel emitters in their sparsely-distributed positions.

If the backplane circuit is large enough relative to the number of pixel emitters it is responsible for driving, the backplane circuit itself may have sufficient area to fanout to all of the pixel emitters of the display (e.g., to itself support electrical connections, such as traces, to each individual microLED being controlled). In this situation, the backplane circuit could be configured to perform all the logical and electrical roles of conventional backplane circuitry, including, without limitation, image processing, data buffering, pixel emitter driving, pulse-width-modulation (PWM) sequencing, and so forth. However, if the integrated circuit is relatively small and/or the number of pixel emitters to be driven and controlled is relatively large, signal routing from one centralized integrated circuit to all the pixel emitters sparsely fanned out across the display area may become impractical. In these situations, one technical solution could involve a first integrated circuit (e.g., a centralized controller circuit) configured with logical backplane circuitry being put in communication with a plurality of additional integrated circuits (e.g., active driver circuits responsible for different tiles into which the display is divided) that drive current to their own respective subsets of the pixel emitters. In certain examples, these driver circuits may also assist the controller circuit with certain logical functions (e.g., buffering, PWM sequencing, etc.), depending on how these tasks are divided up for a given architecture.

As another potential technical solution to address the fanout technical problem, a centralized backplane circuit may perform all the active tasks while relying on passive interposer circuits to assist with signal distribution to respective tiles of the display assembly. In other words, the backplane circuit may perform all the logical and electrical functions of the backplane but may rely on interposer circuits associated with different tiles of the display to help passively distribute signaling to respective subsets of the pixel emitters. Each of these technical solutions to the technical problem of signal distribution to sparsely distributed pixel emitters will be described in more detail below.

Yet another technical problem that must be addressed to construct a shape-adaptive display assembly with transferred integrated circuits and pixel emitters (such as described above) is that the manufacturing process generally requires a rigid substrate to receive integrated circuits (e.g., semiconductor dies, etc.) and pixel emitters (e.g., microLEDs, etc.) being transferred from respective donor wafers where these components were fabricated. Any substrate that might have the flexible properties of the final shape-adaptive display assembly is likely to create issues when components such as integrated circuits and/or pixel emitters are transferred to it.

Methods described herein for fabricating shape-adaptive display assemblies also provide technical solutions to this technical problem. Specifically, as detailed with illustrations and description below, various steps of the fabrication process may involve rigid substrates configured to enable and facilitate the transfer process (e.g., receiving, onto the display assembly, integrated circuitry and pixel emitters that were fabricated elsewhere) and other fabrication steps (e.g., deposition of metal, dielectric, molding, laminate, and/or other layers, etc.). But these rigid substrates may, at appropriate points later in the process, be removed such that the final display assembly has flexible segments along with at least one rigid segment (where a rigid integrated circuit is located).

Various technical effects and benefits may be provided by shape-adaptive display assemblies such as those described herein. First, as mentioned above, sparsely distributing pixel emitters onto a display that is potentially divided into display tiles allows for pixel emitters such as micro light emitting diodes (microLEDs) to be used for direct-view displays that offer significant advantages compared to other display technologies. These advantages include, for example, extremely short response times that allow for responsive displays with bright colors, high frame rates, and high power efficiency. The size of microLEDs also allows for virtually unlimited resolution in direct-view displays, since pixel pitch at which these emitters may be placed can potentially be smaller than the human visual system is even capable of resolving.

Technical effects of such display assemblies being shape-adaptive in the ways described herein are also significant. For example, shape-adaptive display assemblies may help support bezel-less displays and even displays that wrap around edges of their enclosures rather than stopping at the edge. Additionally, shape-adaptive display assemblies may be used to present content on curved surfaces in ways that would be beyond the abilities of conventional (rigid) display assemblies.

Various implementations will now be described in more detail with reference to the figures. It will be understood that particular implementations described below are provided as non-limiting examples and may be applied in various situations. Additionally, it will be understood that other implementations not explicitly described herein may also fall within the scope of the claims set forth below. Shape-adaptive display assemblies described herein, as well as methods for fabricating them, may result in any or all of the technical effects mentioned above, as well as various additional effects and benefits that will be described and/or made apparent below.

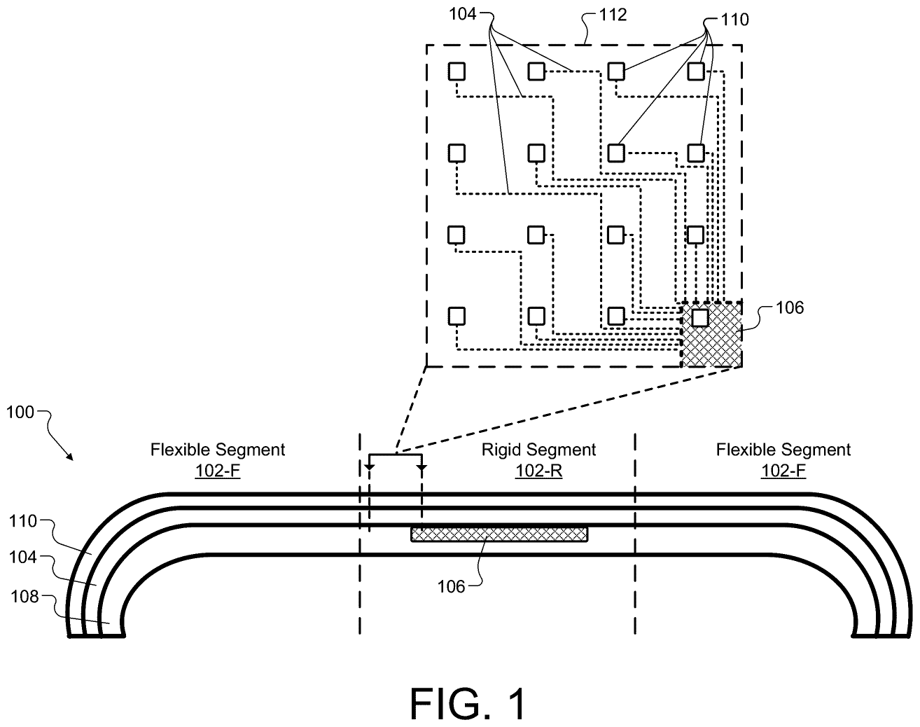

FIG. 1 shows illustrative aspects of an example implementation of a shape adaptive display assembly 100 in accordance with principles described herein. The display assembly 100 in this and other examples below are described as being configured for use as smartwatch displays. It will be understood, however, that the smartwatch use case or application is arbitrarily chosen for purposes of illustration and example. While smartwatch displays provide one good example of an application where implementations of shape-adaptive display assemblies described herein (including display assembly 100) may be used, it will be understood that principles described herein could similarly be used with a variety of other direct-view display applications such as mobile devices, computer screens, television screens, appliance panels, automotive interfaces, and so forth.

As shown in a cutaway side view in FIG. 1, display assembly 100 may include at least one rigid segment 102-R and at least one flexible segment 102-F. The segments may be distributed across the display in any suitable way and may be any respective size and shape as may serve a particular implementation. For example, display assembly 100 could include a centralized rigid segment 102-R surrounded by an outer flexible segment 102-F around the perimeter of the display in one implementation. As another example, one side of the display assembly could be implemented by the rigid segment 102-R while the other side of the display assembly is implemented by the flexible segment 102-F. In still other examples, more than one rigid segment 102-R and/or more than one flexible segment 102-F could be implemented on a single implementation of display assembly 100. In any of these scenarios, it will be understood that the rigid segments 102-R may be configured to maintain a planar (i.e., flat) profile shape, while flexible segments 102-F may be configured to allow for an adaptable (i.e., flexible, bendable) profile shape.

Across both types of segments 102-R and 102-F in FIG. 1, display assembly 100 is shown to be fabricated with various components (on a plurality of layers) configured to perform different functions for the display assembly 100. These components may be fabricated and deposited onto display assembly 100 in ways described in more detail below and include, without limitation: 1) a pattern of conductive material 104 extending over the rigid segment 102-R and the flexible segment 102-F; 2) an integrated circuit 106 disposed on the rigid segment 102-R without extending to the flexible segment 102-F; 3) a molding layer 108 extending over the rigid segment 102-R and the flexible segment 102-F; and 4) a plurality of pixel emitters 110 (not individually depicted in the cutaway side view of display assembly 100 but understood to be distributed across the top layer). Each of these elements of display assembly 100 will now be described in more detail.

The pattern of conductive material 104 may be deposited prior to the other components as display assembly 100 is fabricated, as will be described in more detail below. The pattern of conductive material 104 may have a first side (i.e., the bottom side from the perspective of the cutaway side view in FIG. 1) and a second side opposite the first side (i.e., the top side from the perspective of the cutaway side view in FIG. 1). The conductive material may be distributed in a pattern that is configured to make desired electrical connections between, for example, integrated circuit 106 and the plurality of pixel emitters 110. As such, the pattern of conductive material 104 may include pads configured to connect with terminals of integrated circuit 106 and/or individual pixel emitters 110, traces extending between these pads to conduct current between the terminals in accordance with the desired circuit schematic, and so forth.

As shown in the side profile view in FIG. 1, integrated circuit 106 may be coupled to the first side of the pattern of conductive material 104 (i.e., the bottom of the layer labeled as conductive material 104), while the plurality of pixel emitters 110 may be coupled to the second side of the pattern of conductive material 104 opposite the first side (i.e., the top of the layer labeled as conductive material 104). As is then shown in a top view of a small portion 112 of plurality of pixel emitters 110, the pattern of conductive material 104 may form traces (shown as dotted lines in the top view of portion 112) configured to extend from integrated circuit 106 (a corner of which is shown in the top view of portion 112) to each of the individual pixel emitters 110 (shown as small squares in the top view of portion 112). Conductive material 104 may also include pads to which terminals of pixel emitters 110 and integrated circuit 106 connect (not explicitly shown in the top view of portion 112 since the pads would be obscured by the pixel emitters 110 and integrated circuit 106 resting on the pad).

Integrated circuit 106 may be implemented by a complementary-metal-oxide-semiconductor (CMOS) integrated circuit or another integrated circuit fabricated using another suitable technology. Integrated circuit 106 may be transferred to display assembly 100 after being fabricated elsewhere (e.g., on a donor wafer, as will be described in more detail below). As such, integrated circuit 106 may be implemented as any suitable semiconductor die whether fully packaged, unpackaged, or somewhere in between. In some examples, integrated circuit 106 may be relatively thin and low profile (e.g., with a thickness less than 300 microns, less than 50 microns, less than 20 microns, etc.). As shown, because integrated circuit 106 may be fabricated on a rigid silicon wafer (typical of CMOS fabrication) and may itself be rigid, integrated circuit 106 is disposed entirely within rigid segment 102-R without extending to flexible segments 102-F.

As mentioned above and as will be described in more detail below, integrated circuit 106 may be configured to perform different functions with respect to the plurality of pixel emitters 110 based on the architecture used for a certain implementation. For example, integrated circuit 106 could, in certain implementations, be implemented as a backplane circuit that performs all the logical and electrical functions of a conventional display backplane. This could be done directly (if the integrated circuit 106 has a direct connection to each pixel emitter 110, as shown) or by way of passive interposer circuits that may assist with the routing (in cases where there are too many pixel emitters 110 for integrated circuit 106 to be directly connected to each of them). In other implementations, integrated circuit 106 could be implemented as a controller circuit that is not connected directly to the pixel emitters 110 (or at least is not connected directly to many of them) but, rather, is configured to indirectly control the pixel emitters 110 by way of connections to a plurality of additional integrated circuits referred to herein as driver circuits. In these types of examples, logical backplane functions such as buffering, PWM sequencing, and so forth, may be distributed between the controller circuit and the driver circuits in a variety of ways depending on the architecture selected for a certain application. The electrical backplane functions (e.g., driving current to the individual pixel emitters 110 to turn them on and off in accordance with a PWM scheme) may, however, be performed by the driver circuits under direction from the controller circuit.

Molding layer 108 is shown to extend across the entire display assembly 100 on the first side (i.e., bottom side) of the pattern of conductive material 104. This layer may be configured to help mechanically hold display assembly 100 together, and, as such, may encapsulate integrated circuit 106 as shown. Molding layer 108 may be implemented with organic or inorganic materials, as will be described in more detail below. For example, it may be desirable to deposit a molding material that is ultraviolet (UV) cured with a low shrinkage parameter.

The plurality of pixel emitters 110 may be implemented by a set of micro light emitting diodes (microLEDs) or another suitable type of light emitter. As will be described in more detail below, these microLEDs may be fabricated elsewhere (e.g., a donor wafer) and transferred to display assembly 100 as part of the fabrication of display assembly 100. In some examples, the plurality of pixel emitters 110 may be fabricated at a first pitch on the donor wafer (e.g., a pitch that is too small for the human visual system to resolve without magnification), while being coupled to the pattern of conductive material 104 of display assembly 100 at a second pitch that is larger than the first pitch (e.g., a pitch that is more reasonably resolvable by humans without magnification, though the pixel resolution associated with the second pitch could still be very high). While each of the plurality of pixel emitters 110 may be coupled, by way of conductive material 104, to an integrated circuit (e.g., integrated circuit 106 or an additional integrated circuit not shown), the top view of portion 112 shows that certain pixel emitters 110 may be distributed away from the integrated circuit (e.g., on rigid segment 102-R or flexible segment 102-F) while other pixel emitters 110 may be right on top of the integrated circuit.

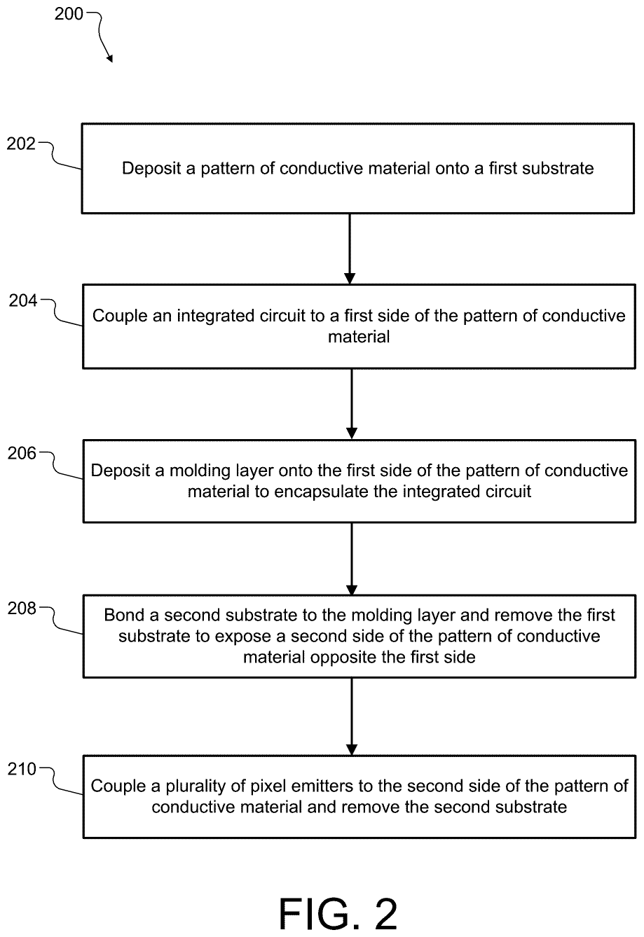

FIG. 2 shows an illustrative method 200 for fabricating (i.e., assembling, constructing, manufacturing, etc.) a shape-adaptive display assembly having a rigid segment and a flexible segment (i.e., such as the display assembly 100 illustrated and described above). It will be understood that method 200, as well as other similar methods described herein (and/or variants of method 200 in accordance with principles described herein) may, in certain examples, be encoded in instructions that may be stored by a non-transitory computer-readable medium. When executed, these instructions could cause a processor of a computing device (e.g., a display fabrication system) to perform one or more of the operations of method 200. While FIG. 2 shows illustrative operations 202-210 according to a specific implementation, it will be understood that other implementations of this method may omit, add to, reorder, and/or modify any of operations 202-210 that are explicitly represented in FIG. 2. Additionally, while operations shown in FIG. 2 are illustrated with arrows suggestive of a sequential order of operation, it will be understood that some of the operations of method 200 could be performed concurrently (e.g., in parallel with one another) in certain implementations. Each of the operations of these methods will now be described in more detail as the operations may be performed by a system such as a display fabrication system. These and other operations will also be illustrated and described in more detail below with reference to certain variations that may be applied in certain implementations.

At operation 202, a display fabrication system may deposit a pattern of conductive material onto a first substrate. This first substrate could be implemented as a rigid silicon substrate, sapphire substrate, glass substrate, or other carrier substrate of another suitable material onto which conductive material may be deposited using lithographic deposition techniques. The conductive material deposited at operation 202 may be patterned to form pads and traces that are preconfigured to connect an integrated circuit (e.g., a controller circuit, a driver circuit, etc.) to a plurality of pixel emitters (e.g., microLEDs). This conductive material could be implemented as copper, indium tin oxide (ITO), or another suitable conductor material. In some examples, the pads and traces could be fabricated from the same type of conductive material (e.g., ITO), while in other examples different types of conductive material could be included in the same pattern (e.g., ITO traces with copper pads, etc.). In some examples, a single redistribution layer of conductive material may be sufficient to form the desired electrical connections. In other examples, operation 202 could include depositing multiple redistribution layers (i.e., multiple layers of patterned conductive material) that are separated by layers of insulative (i.e., dielectric) material to keep current flow between the layers separated. Vias or other methods of moving signaling between layers may be used to ensure that the desired routing is implemented.

At operation 204, the display fabrication system may couple an integrated circuit to a first side of the pattern of conductive material. More particularly, the integrated circuit may be bonded to various connections (e.g., pads) formed from the conductive material on a first side that is opposite the side deposited onto the first substrate. As mentioned above, the display assembly being fabricated is configured to include a rigid segment and a flexible segment. While the conductive material deposited at operation 202 may extend across the entire display (i.e., across both the rigid and flexible segments), the integrated circuit coupled to the pattern of conductive material at operation 204 may specifically be disposed only on the rigid segment (i.e., without extending to the flexible segment). In this way, the rigid integrated circuit may not be improperly bent or flexed when the display assembly is complete (since the integrated circuit itself may be rigid and need to remain flat), while other portions of the display assembly may be bent and flexed as desired.

At operation 206, the display fabrication system may deposit a molding layer onto the first side of the pattern of conductive material (i.e., the side opposite the side facing the first substrate and the same side on which the integrated circuit is coupled). The molding layer deposited at operation 206 may be configured to encapsulate the integrated circuit that was coupled at operation 204, but, like the pattern of conductive material deposited at operation 202, may extend over both the rigid segment and the flexible segment of the display assembly. As part of depositing the molding layer, the material of the molding layer may be cured. Ultimately, this material may be configured to be shape adaptive, though at this point in the process, the assembly being fabricated would be entirely rigid due to the presence of the first substrate.

At operation 208, the display fabrication system may bond a second substrate to the molding layer (e.g., after the molding layer has been cured, such as by being exposed to UV light). This second substrate may be similar to the first substrate (e.g., constructed of the same or similarly rigid materials, etc.) and may be configured to perform a similar carrier role of holding the display elements together as they are assembled in the fabrication process. However, by the addition of the second substrate to the molding layer (i.e., on the opposite side of the display assembly from the first substrate) the need for the rigid first substrate is obviated, such that the first substrate may be removed as part of operation 208 (e.g., once the second substrate is in place). As the first substrate is removed, a second side of the pattern of conductive material (opposite the first side of the pattern of conductive material to which the integrated circuit and molding layer are connected) may be exposed.

At operation 210, the display fabrication system may then couple a plurality of pixel emitters to this exposed second side of the pattern of conductive material. For example, as will be described and illustrated in more detail below, pixel emitters fabricated on a separate donor wafer may be transferred to the pads of conductive material that have been prepared for this purpose. While this transfer process may require or be greatly facilitated by a rigid display assembly, the second substrate may no longer be needed once the pixel emitters have been properly placed (and, in certain examples, other steps such as lamination have been performed). Accordingly, part of operation 210 may also include removing the second substrate so that the flexible segment of the completed display assembly may actually become shape adaptive (i.e., flexible and bendable). In other words, while the integrated circuit, the first substrate, and the second substrate may all be rigid (i.e., not shape adaptive), if the conductive material and the molding layer are flexible, the fully-fabricated display assembly that results when method 200 is complete (and the first and second substrates are removed) may include both the rigid segment (which hosts the rigid integrated circuit and is configured to maintain a planar profile shape) and the flexible segment (which hosts at least some of the pixel emitters and is configured to allow for an adaptable profile shape).

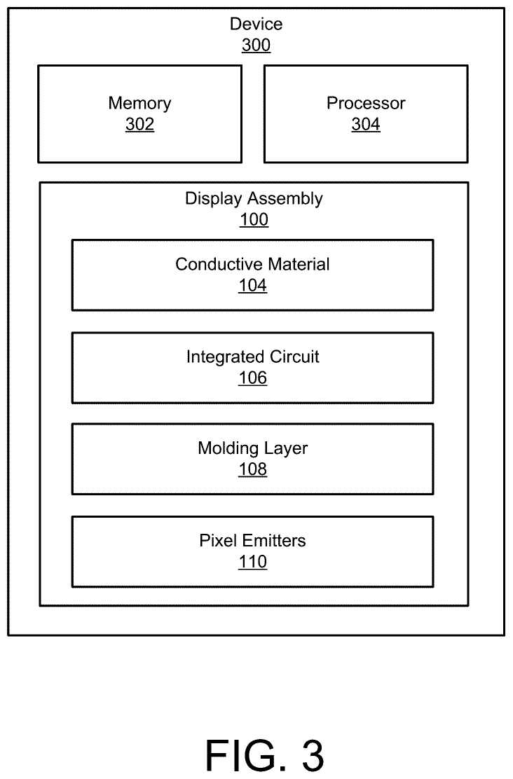

FIG. 3 shows an illustrative device 300 that includes, among other components, a shape-adaptive display assembly in accordance with principles described herein. Specifically, as shown, device 300 may include an implementation of display assembly 100 that will be understood to have a rigid segment with a planar profile shape (such as rigid segment 102-R described above) and a flexible segment with a non-planar profile shape (such as flexible segment 102-F described above). As shown, this display assembly may include various elements that have been described, such as: 1) a pattern of conductive material 104 extending over the rigid segment and the flexible segment; 2) an integrated circuit 106 disposed on the rigid segment without extending to the flexible segment, the integrated circuit coupled to a first side of the pattern of conductive material; 3) a molding layer 108 extending over the rigid segment and the flexible segment, the molding layer deposited on the first side of the pattern of conductive material and encapsulating the integrated circuit; and 4) a plurality of pixel emitters coupled to a second side of the pattern of conductive material opposite the first side of the pattern of conductive material.

Along with the display assembly 100, device 300 is shown to include other elements such as a memory 302 and a processor 304. Memory 302 may be configured to store instructions (e.g., computer code, image data, etc.) such that processor 304, which may be communicatively coupled to memory 302, may be configured to execute the instructions to present image content. More particularly, when processor 304 executes the instructions, processor 304 may present the image content by communicating with integrated circuit 106 and thereby causing the plurality of pixel emitters 110 to display the image content.

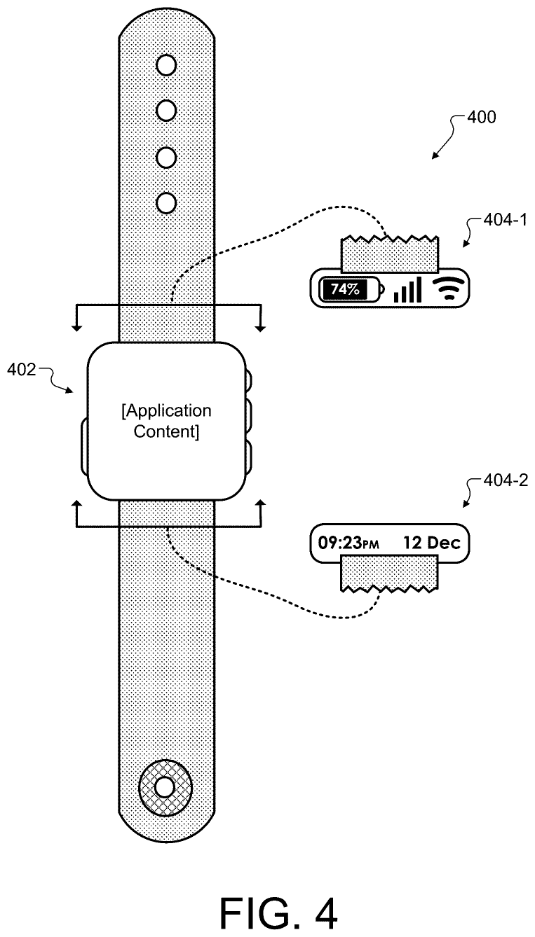

Device 300 may be implemented as any computing device or other type of apparatus configured to display image content (e.g., static image content, video content, interactive content, etc.). As has been mentioned, for example, device 300 could be implemented by a device such as a mobile device (e.g., a smartphone, tablet, eReader, etc.), an extended reality device (e.g., a virtual and augmented reality headset), a computer monitor, a television, an appliance or other object that features a display screen, a vehicle dashboard display, or the like. There may be certain advantages for any of these types of devices if their image displays can include flexible segments such as flexible segments 102-F of display assembly 100. Another suitable way that device 300 may be implemented is as a smartwatch device such as will now be illustrated in relation to FIG. 4.

FIG. 4 shows illustrative aspects of a smartwatch device 400 that is presented as a particular example of device 300 described above. As shown, smartwatch device 400 may include a main portion 402 that displays a first type of content (labeled “[Application Content]”) such as may be selected by a user of smartwatch device 400. For example, smartwatch device 400 may store and be configured to execute various apps such as exercise apps, weather apps, scheduling apps, messaging apps, mapping apps, photo and video apps, and so forth. The content displayed in connection with these apps may generally be of primary interest to the user and, as such, may be presented on main portion 402.

However, other content that may be semantically distinct from this application content may also be of at least some interest (e.g., occasional interest) during the use of these apps. For example, time, date, weather, or other such information could be of occasional interest to the user independent from whatever activity they are engaged in with a particular app executing on main portion 402. As another example, status information for the smartwatch device 400 itself (e.g., connectivity information, battery information, etc.) could similarly be of occasional interest independent from the application content.

As such, FIG. 4 shows that a display assembly implemented as the display of smartwatch device 400 may include not only a first set of pixel emitters within a rigid segment associated with main portion 402, but also additional sets of pixel emitters within flexible segments associated with, for example, a device status portion 404-1 and a contextual portion 404-2. As shown, while the first set of pixel emitters is configured to display first content (e.g., Application Content) that the user may primarily interact with, a second set (and/or additional sets) of pixel emitters may be configured to display semantically distinct content such as the device status content shown in portion 404-1 (e.g., a battery life that smartwatch device 400 has remaining, a signal strength of the Wi-Fi and/or cellular connection the watch has, etc.) and the contextual content shown in portion 404-2 (e.g., the time, the date, etc.). This content is considered to be semantically independent from the application content since, presumably, the executing app itself is not extended onto these auxiliary segments of the display (i.e., they are visually separable from main portion 402), nor does the executing app directly influence the information represented on these segments. In other configurations, however, it will be understood that these segments could instead present an extension of the content presented on main portion 402 or they could otherwise be semantically related to that application content.

The views of device status portion 404-1 and contextual portion 404-2 are shown in FIG. 4 to be approximately perpendicular (or arranged at another non-zero angle) relative to the flat face of main portion 402. In other words, as illustrated, these portions of the display may be disposed on the bottom and top sides of smartwatch device 400 where the watch band connects. In some examples, other sides of smartwatch device 400 could similarly host flexible segments of the display as may serve a particular implementation.

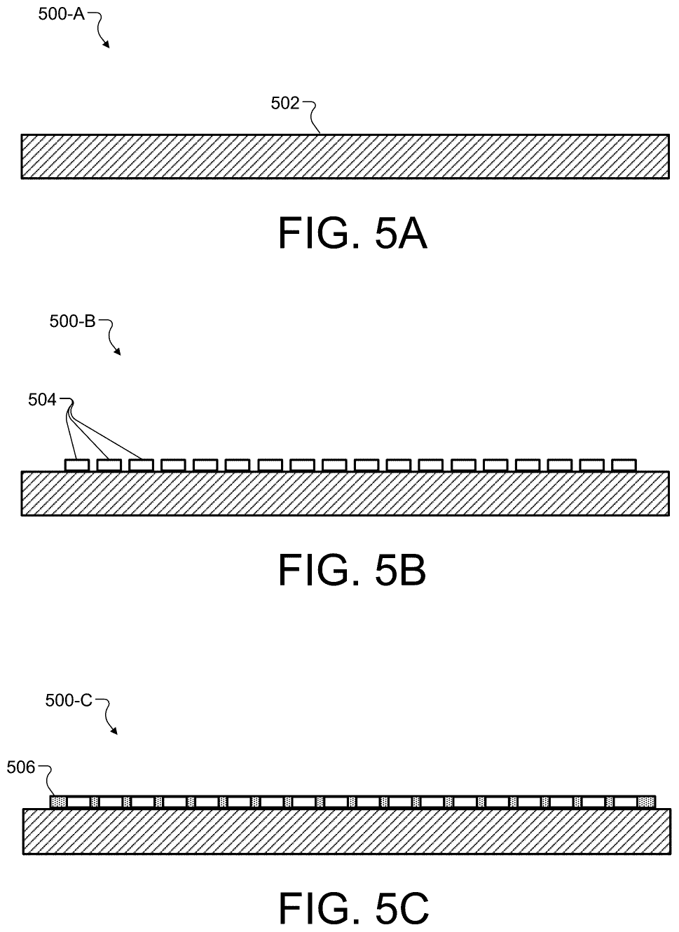

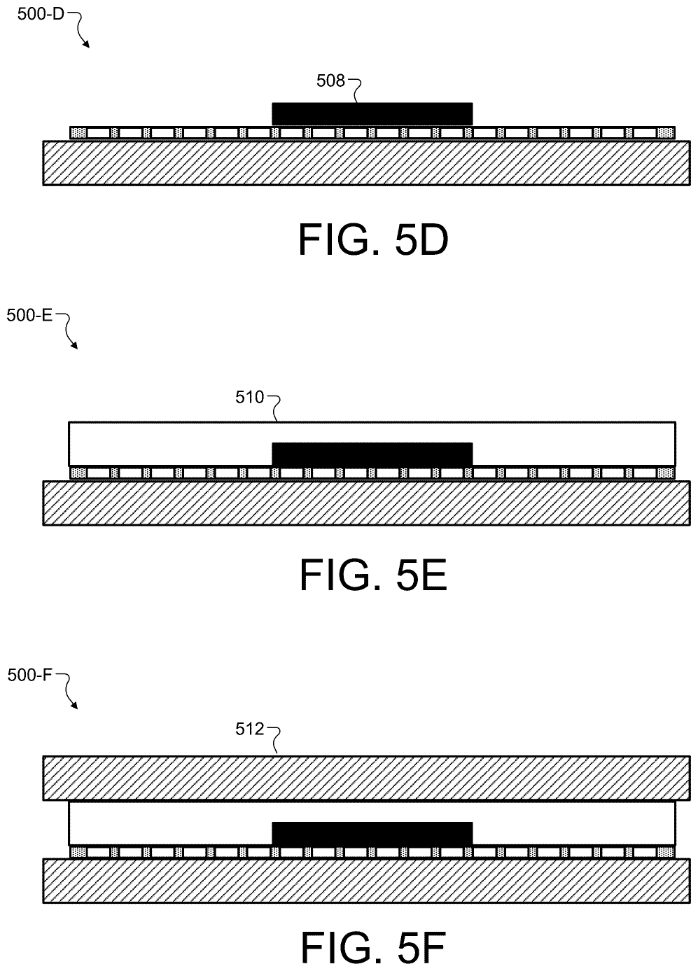

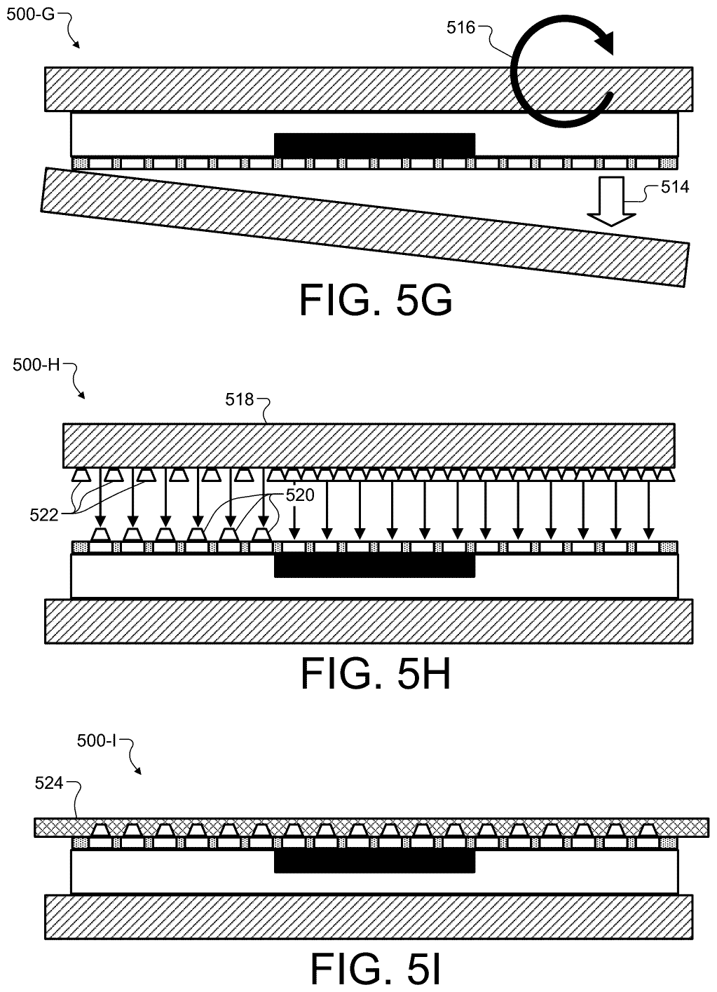

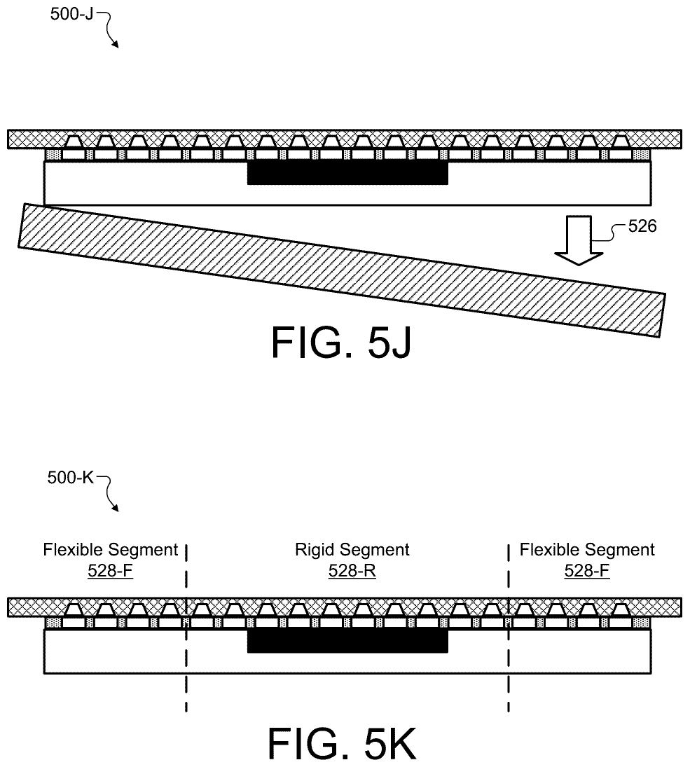

FIGS. 5A-5K show illustrative aspects of fabricating a shape-adaptive display assembly in various stages 500-A (in FIG. 5A) through 500-K (in FIG. 5K) in accordance with principles described herein. More particularly, at each stage, the display assembly being assembled is shown in a cutaway side view configured to illustrate the various layers of the display assembly being constructed. In FIGS. 5A-5K, newly added elements will be explicitly labeled with reference numbers and described in relation to the figure. Elements from previous stages, which will have already been described, will be depicted to provide context of the display assembly being assembled, but these will not be explicitly labeled again after first being introduced.

FIG. 5A shows a stage 500-A in which a first substrate 502 is constructed or obtained for use as a carrier substrate. As has been described above, substrate 502 may be a rigid substrate configured to provide structural support and facilitate holding various elements of the display assembly together as the fabrication is performed. To this end, substrate 502 may be constructed from silicon, sapphire, glass, or another suitable material.

FIG. 5B shows a stage 500-B in which a pattern of conductive material 504 is deposited on substrate 502. From the side view of FIGS. 5A-5K, conductive material 504 is shown to include a number of pads that are relatively close together given their size. It will be understood, as described herein, that this depiction is not necessarily to scale and that the distribution of pads hosting pixel emitters may be distributed relatively sparsely (in relation to the potentially very small size of microLEDs, for example) in certain examples. It will also be understood that traces connecting the pads in a pattern (similarly as shown in FIG. 1) may be included in this metal layer, and that, in certain implementations, multiple layers of conductive material may be employed rather than the one layer shown here.

As shown, the conductive material (e.g., ITO, copper, both, other types of metal, etc.) may implement electrical contacts for the emitter bonding process and will be manufactured directly onto the first carrier substrate 502. In one particular example, the pattern of conductive material deposited at stage 500-B may include traces of a first conductive material connecting to pads of a second conductive material. The first conductive material may be an indium tin oxide (ITO) material while the second conductive material may be a copper material. In other examples, both the first and second conductive materials may be an ITO material, both may be copper, or other combinations of materials may be used. One advantage of ITO material, particularly when used for the traces, is that it may be transparent to visible light such that traces running between pixel emitters need not be visible or obscure underlying circuitry (e.g., antennas, biometric sensors, etc.).

As will be made apparent, this deposition of electrical contacts (i.e., redistribution layers or RDL) first may allow for additional elements to be built up on either side of the electrical contacts so that all of the rigid carrier substrates may eventually be removed to leave a finished display assembly with at least some flexible portions (e.g., where rigid integrated circuits are not placed).

FIG. 5C shows a stage 500-C in which the pattern of conductive material 504 is covered by a dielectric (i.e., insulative) material 506. In other words, prior to coupling any integrated circuit to the pattern of conductive material 504 (as will be described in later stages), stage 500-C involves depositing dielectric material over the pattern of conductive material 504 to isolate different portions of the conductive material from one another, as well as to provide structural stability to the pattern of conductive material 504. As mentioned above, in some implementations, multiple layers of patterned conductive material may be deposited with dielectric material 506 being used to isolate each one. In other words, several rounds of stage 500-B and 500-C could be interleaved before moving on to further stages of the fabrication process.

The dielectric material 506 deposited in stage 500-C may be any suitable material such as silicon nitride (SiN), silicon oxide (SiO), or another suitable dielectric. This material may be deposited over the entirety of the pattern of conductive material 504 and then planarized (e.g., using a chemical-mechanical polishing (CMP) technique, etc.) to re-expose the contacts as appropriate (e.g., exposing the entire pattern of conductive material 504, exposing the pads while leaving the traces covered, etc.). After stages 500-B and 500-C are complete (including multiple iterations of each in some examples), the electrical interconnect for the display assembly may be accessible from the top side using lithography, etch, CMP and or a combination of the individual processes.

FIG. 5D shows a stage 500-D in which an integrated circuit 508 is coupled to a first side (i.e., a top side in the orientation shown) of the pattern of conductive material 504. As shown, certain pads of conductive material 504 prepared for certain pixel emitters (which will be added later) may couple directly to integrated circuit 508 as integrated circuit 508 lays on top of these pads. Other electrical connections to which integrated circuit 508 may be coupled (not explicitly shown) will be understood to connect to other pads of the conductive material 504 that are not directly placed under integrated circuit 508. For example, all of the pads of conductive material 504 shown in these figures could electrically connect to integrated circuit 508 using traces such as illustrated above in portion 112 of FIG. 1.

The coupling of integrated circuit 508 onto the exposed electrical contacts of conductive material 504 may involve aligning the integrated circuit (e.g., a functional die) with the intended placement on the pattern of electrical contacts, and then using a die-to-wafer bonding approach to bond the die with the conductive material 504. In certain implementations, a low temperature (e.g., <300° C.) interconnect technology may be used. In examples where multiple integrated circuits are included beyond integrated circuit 508 (as is the case for certain implementations described in more detail below), the multiple integrated circuits may be placed and bonded at stage 500-D and then, as part of stage 500-D, these integrated circuits may be laterally connected to one other (e.g., using one or more additional layers of conductive material 504 and dielectric material 506) to provide intercommunication between the integrated circuits themselves.

FIG. 5E shows a stage 500-E that may follow bonding of the integrated circuit 508 (and any other integrated circuits as may be included for a certain implementation) to the electrical connections that have been deposited (i.e., implemented by the patterns of conductive material 504 and the dielectric material 506). At stage 500-E, a molding layer 510 is shown to be deposited in a way that encapsulates the integrated circuit 508 and that covers the layers of conductive material 504 and dielectric material 506. Molding layer 510 may be constructed of an organic material in certain implementations. For instance, the organic material may be an epoxy resin or other UV-cured material that is deposited and cured at stage 500-E. In other implementations molding layer 510 could be constructed of a non-organic material such as an oxide that could perform a similar role.

FIG. 5F shows a stage 500-F in which molding layer 510 is coupled to a second substrate 512 that, like first substrate 502, may be constructed or obtained for use as a carrier substrate. Second substrate 512 may serve a similar role as substrate 502, providing structural support to the display assembly during various stages of the fabrication process. As such, second substrate 512 may be implemented by a rigid substrate of the same or a similar material as described above for substrate 502 (e.g., silicon, sapphire, glass, etc.). Like substrate 502, substrate 512 may be a temporary carrier substrate that will not be included (as described in more detail below) as part of the final display assembly being produced. Accordingly, either or both of substrates 502 and 512 may be reused (e.g., after proper cleaning and preparation) after performing similar roles in the production of other display assemblies. Second substrate 512 may be bonded or otherwise coupled to molding layer 510 in any suitable way.

With substrate 512 being bonded to molding layer 510, FIG. 5G shows a stage 500-G in which substrate 502 may be removed to thereby expose the second side of the conductive material 504. As mentioned above, second substrate 512 may provide structural support for the display assembly as substrate 502 is removed. A removal 514 of substrate 502 is represented in FIG. 5G by an arrow showing substrate 502 being separated from the bottom of the display assembly. As removal 514 is performed, FIG. 5G shows that conductive material 504 and dielectric material 506, which have been prepared in earlier stages, may now be exposed on a second side (opposite the side connecting to integrated circuit 508 and molding layer 510). In some cases, the newly exposed interconnects may be cleaned, polished, and otherwise prepared as part of removal 514.

Also shown at stage 500-G is an arrow 516 representing a change in orientation of the display assembly being constructed. As arrow 516 shows, the display assembly may be flipped 180° so that, in subsequent stages, substrate 512 will be illustrated on the bottom of the stack (rather than on the top as shown at stage 500-G), and the newly-exposed second side of the conductive material 504 will be oriented upwards, rather than downwards.

FIG. 5H shows a stage 500-H in which pixel emitters are coupled to the exposed conductive material 504 (now facing upward after the rotation of arrow 516 at stage 500-G, as described above). More particularly, a large number of pixel emitters (e.g., microLEDs) may be fabricated on a donor wafer that includes yet another substrate 518 that, like substrates 502 and/or 512, may be constructed of silicon or another suitable material. The pixel emitters on substrate 518 may be fabricated at a relatively small pixel pitch (i.e., very close together). Indeed, in some examples, the pixel pitch at which the pixel emitters are fabricated may be so small that the pixel emitters may be far too small and close together to be individually resolved or appreciated by the human visual system. Accordingly, as shown, some of these pixel emitters (labeled as pixel emitters 520 and including every other emitter in this example) may be transferred (i.e., released) from substrate 518 to a pad of conductive material 504 that has been prepared to host and connect the pixel emitter to integrated circuit 508. Meanwhile, other pixel emitters fabricated on substrate 518 of the donor wafer (labeled as pixel emitters 522) may remain attached to substrate 518 so that they can be used for a different purpose (e.g., transferred to a different display assembly, etc.).

The snapshot of stage 500-H shown in FIG. 5H shows the pixel emitter transfer process in the middle of the process, where some pixel emitters 520 have been released (as indicated by arrows showing their origin on substrate 518) while other pixel emitters have yet to be released (as indicated by arrows indicating the destination to which they will be transferred). While this illustration shows every other pixel emitter from substrate 518 being released to a prepared pad of conductive material 504, it will be understood that the increase in pixel pitch from the donor wafer to the display assembly may, in some examples, be more significant. For example, if the pixel pitch were to increase by a factor of 40, only one in every 40 pixel emitters may be transferred as a pixel emitter 520 while the other 39 may remain connected to substrate 518 as pixel emitters 522. Similarly, it will be understood that some of the pixel emitters originally fabricated on the donor wafer may have already been transferred (e.g., to other display assemblies) prior to stage 500-H of the display assembly being produced in the illustration. In this example, substrate 518 may already have certain pixel emitters removed while others are being transferred as pixel emitters 520.

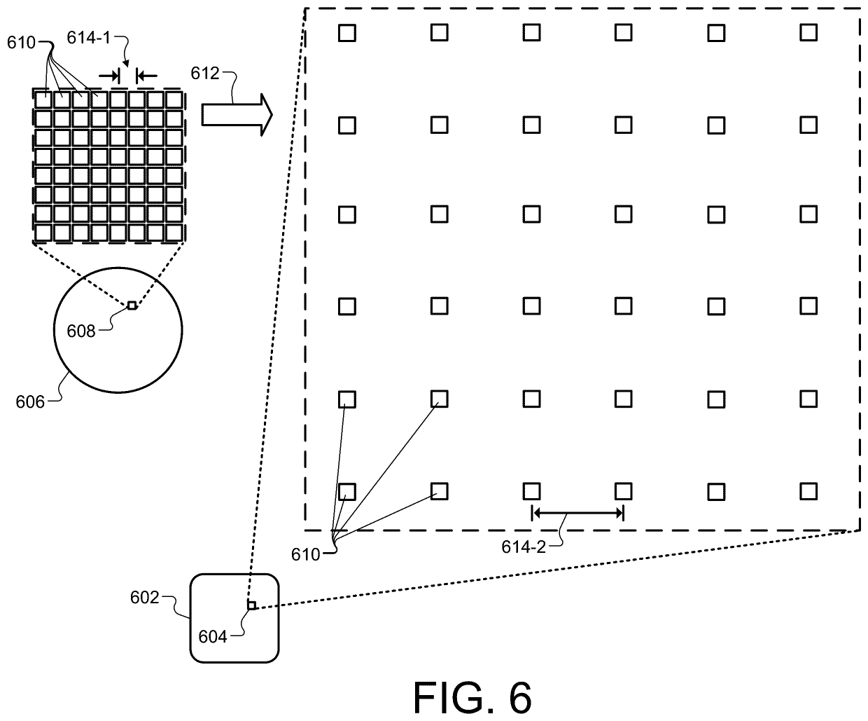

To further illustrate certain aspects of the transferring of pixel emitters performed at stage 500-H, FIG. 6 shows a set of pixel emitters being transferred to a display assembly (e.g., the display assembly being produced in FIGS. 5A-5K) after fabrication of the set of pixel emitters elsewhere (e.g., on a donor wafer such as represented by substrate 518).

More particularly, FIG. 6 illustrates aspects of a display assembly implementation such as any of those described herein. In this example, a direct-view display 602 is illustrated and described as being configured for use as a smartwatch display (e.g., based on its shape, size, etc.). However, as mentioned above, it will be understood that the same principles described in relation to direct-view display 602 may be applied to other types of direct-view displays configured for use in other applications such as mobile device displays, laptop screens, televisions, appliance panels, and so forth.

As shown in FIG. 6, a small segment 604 of direct-view display 602 is broken out and zoomed in to illustrate certain aspects of the display that will be described. Additionally, FIG. 6 shows a donor wafer 606 (not drawn to scale in relation to direct-view display 602) that may undergo lithographic and/or other processing to fabricate a large number of pixel emitters (e.g., microLED devices or the like). More particularly, as shown by a small segment 608 of donor wafer 606 that is similarly shown to be broken out and zoomed into, a set of pixel emitters 610 (represented by small squares within segment 608, only a few of which are explicitly labeled) is fabricated on donor wafer 606 before undergoing a transfer 612 to direct-view display 602. The set of pixel emitters 610 will be understood to correspond to the set of pixel emitters that includes both pixel emitters 520 and 522 described above in relation to FIG. 5H. As mentioned, it will be understood that the set of pixel emitters 610 produced on donor wafer 606 may be transferred not only to direct-view display 602 but also to one or more other display assemblies. For example, pixel emitters fabricated on one large donor wafer may be transferred to dozens or hundreds of relatively small display assemblies (such as smartwatch displays).

Segment 604 shows that the set of pixel emitters 610 is disposed in direct-view display 602 subsequent to being transferred (transfer 612) to the direct-view display 602 from the donor wafer 606 on which the set of pixel emitters 610 was fabricated. As further illustrated in FIG. 6, the set of pixel emitters 610 may be fabricated at a first pixel pitch 614-1 and may be distributed on the direct-view display 602 (e.g., the pads of conductive material 504 of the display assembly shown in FIGS. 5A-5K) at a second pixel pitch 614-2 that is greater than pixel pitch 614-1. In some examples, the pixel pitch 614-1 at which the set of pixel emitters 610 are fabricated may be a very small pixel pitch, such as in the range of about 6-4 microns. In contrast, the pixel pitch 614-2 at which the set of pixel emitters 610 is distributed within the direct-view display 602 may be significantly larger than pixel pitch 614-1. While not necessarily drawn to scale in relation to pixel pitch 614-1 in FIG. 6, pixel pitch 614-2 could be, in various examples, at least double pixel pitch 614-1, at least four times greater than pixel pitch 614-1, at least ten times greater than pixel pitch 614-1, at least twenty times greater than pixel pitch 614-1, at least forty times greater than pixel pitch 614-1, or another suitable increase as may serve a particular implementation. As a specific example, for instance, pixel pitch 614-1 could represent a high-density pitch in the range of 6-4 microns while pixel pitch 614-2 could represent a low-density (sparse) pitch in the range of 50-120 microns (e.g., 80 microns).

While transfer 612 may involve spacing out the set of pixel emitters 610 to a significantly greater pixel pitch, it may not be the case that every individual emitter (e.g., every microLED fabricated on donor wafer 606) is spaced equally sparsely from the others. For example, individual pixel emitters (e.g., red, green, and blue microLEDs, also referred to as subpixels) may be distributed individually at pixel pitch 614-2 in certain implementations, while, in other implementations, these individual subpixels may be clustered together into emitter clusters that each include all the primary colors (e.g., clusters that include at least one red, at least one green, and at least one blue microLED) and are distributed with the larger pixel pitch 614-2. In certain examples, different donor wafers could be used to fabricate different pixel emitter colors (e.g., a donor wafer for red pixel emitters, a donor wafer for green pixel emitters, and a donor wafer for blue pixel emitters, etc.) and then transfers from each of these donor wafers could combine to create the multicolor pixel array.

One advantage of having pixel emitters distributed relatively sparsely (i.e., with a pitch such as shown by pixel pitch 614-2) is that the space between sparsely-distributed pixel emitters may be used by other components (e.g., antennas, alternate wavelength emitters, imaging sensors, ambient light sensors, etc.). For example, these spaces may provide placement locations for the other components (e.g., when integrated directly into the display assembly) or may at least facilitate surface access and visibility for such components (e.g., in the event they are placed beneath the display assembly, deeper into the device).

To illustrate how such usage could be advantageous, a conventional display assembly will be considered. If an antenna or set of sensors (e.g., light detectors for a fingerprint reader, etc.) were to be integrated into a device such as a smartwatch, these components would typically need to be placed beneath the conventional display assembly. Such placement would not be ideal, since the antenna or sensors would be farther from the surface of the display, forcing attenuation of signals that are transmitted and/or received through the display itself. In contrast, the ample space between sparsely distributed pixel emitters 610 (as illustrated in FIG. 6) leaves room for such components to be integrated directly into the display assembly so that they are located right at the surface and have direct access and visibility. For example, an antenna could be made to weave between the pixel emitters (e.g., on a redistribution layer without traces or with fewer traces connecting the emitters to their respective driver circuit) so that it could be right at the surface and not buried deeper in the device under the display assembly. As another example, many small sensors such as might be used to capture an image (e.g., sensors forming a camera, a fingerprint or facial identity detector, an ambient light detector, etc.) could be interspersed with the pixel emitters and routed to a controller in a similar way as described herein for the pixel emitters.

Even if antennas and sensors (such as have been described) are not integrated into the display assembly itself in these ways, the sparseness of the pixel emitters and potential thinness of display assemblies described herein may mitigate the antenna/sensor issues described above (i.e., issues faced by conventional display assemblies). For example, even for antennas and sensors that happen to be incorporated outside of the display assembly (e.g., deeper within a device, beneath the display assembly), the relatively sparse distribution of pixel emitters and the flexibility with which they may be placed may facilitate surface access for antennas and sensors anywhere within the device.

Whether distributed individually or in clusters, and whether transferred from one or multiple donor wafers, the set of pixel emitters 610 may be arranged on the display assembly with respect to a lattice that includes a plurality of pixel nodes where the individual pixel emitters or clusters of pixel emitters are placed. In other words, the set of pixel emitters 610 may be fabricated at first pixel pitch 614-1 on donor wafer 606 and this first pixel pitch 614-1 may be smaller than the second pixel pitch 614-2 at which the plurality of pixel nodes is disposed on the lattice. To illustrate, the example of FIG. 6 shows a rectilinear lattice that includes pixel nodes arranged in a grid of rows and columns. While such a rectilinear lattice may be appropriate or optimal for certain implementations, it will be understood that the shape and lattice type into which pixel emitters are arranged need not be rectilinear. For instance, pixel emitters could be disposed on a triangular lattice, a hexagonal lattice, a lattice with serpentine rows and/or columns (rather than straight rows and columns such as illustrated in FIG. 6), another suitable type of lattice, or even no lattice at all (e.g., an irregular pattern). For example, this flexibility in pixel emitter placement and shaping, as well as the sparseness of the pixel emitters, may facilitate the placement and function of certain components under the display assembly. For example, one or more antennas (e.g., near-field communication (NFC) antennas) beneath display assembly may have significant visibility for wireless communication through the gaps between the pixel emitters, sensors (e.g., cameras, fingerprint readers, facial recognition modules, etc.) could be placed under the display, and so forth.

Returning to the fabrication stages of FIGS. 5A-5K, FIG. 5I shows a stage 500-I subsequent to the coupling of the plurality of pixel emitters 520 to the second side of the pattern of conductive material 504 (and prior to second substrate 512 being removed, as will be described at a later step). At stage 500-I, a laminate layer 524 is shown to be deposited over the plurality of pixel emitters 520. Laminate layer 524 may be implemented as a film (e.g., constructed of an acrylic material and coupled to the display assembly by adhesion) and may serve multiple functions when the display assembly is fully fabricated. As one example function, laminate layer 524 may be configured to help hold the display assembly together when it is not structurally supported by any rigid substrate (such as substrates 502 or 512, which are removed for the final display assembly). The final display may be extremely thin (e.g., relative to a display assembly constructed on a silicon substrate) and so this laminate layer 524 may be useful for providing that structural support to the other layers as the display assembly undergoes the final stages and is used as a finished product. Additionally, another example function of laminate layer 524 may be to encapsulate and provide protection to the small and delicate pixel emitters 520 and associated circuitry (e.g., traces of conductive material 504, etc.), which would otherwise be exposed. Accordingly, laminate layer 524 may be transparent to allow emitted light to freely pass through from the pixel emitters.

FIG. 5J shows a stage 500-J in which, after laminate layer 524 has been applied, a removal 526 of second substrate 512 may be performed, leaving only the layers of conductive material 504 and dielectric material 506, the integrated circuit 508, the molding layer 510, the pixel emitters 520, and the laminate layer 524 as part of the final product.

While only one display assembly is shown in the various assembly stages of FIGS. 5A-5K, it will be understood that a plurality of display assemblies may be fabricated at the same time and using certain shared resources. For example, dozens or hundreds of smartwatch display assemblies may fit on substrates 502 and 512, and each of these may undergo, in parallel, the same stages illustrated for the specific display assembly shown in FIG. 5A-5K. After laminate layer 524 has been applied and removal 526 has occurred, the multiple displays (in examples where multiple displays have been fabricated on substrate 512) may be separated from one another using a dicing process. For example, the laminate layer deposited over all the individual displays may hold individual display assemblies together as a dicing frame is applied to the whole assembly. Laser-based or saw-based scoring, dicing, deburring, and so forth may then be performed to separate the various display assemblies into standalone units. In certain implementations, a removable layer of protective material (e.g., acrylic tape, etc.) may be applied in addition to or as an alternative to laminate layer 524 (which was described above as constituting a permanent layer that remains on the finished display assembly). This temporary layer could help during the dicing process but may then be removed when the display assembly is installed as part of a device (e.g., smartwatch device 400, etc.).

FIG. 5K shows a final stage 500-K in which the display assembly is complete. As shown, only the layers of conductive material 504 and dielectric material 506, the integrated circuit 508, the molding layer 510, the pixel emitters 520, and the laminate layer 524 are included as part of the final product (since other elements used during the process, such as substrate 502, substrate 512, substrate 518 and pixel emitters 522, etc., were removed or are otherwise not part of this display assembly). Similarly as described above in relation to display assembly 100 and its segments 102-R and 102-F, the final display assembly illustrated at stage 500-K is shown to include a rigid segment 528-R that includes the rigid integrated circuit 508 and is configured to maintain a planar profile shape, along with flexible segments 528-F that are configured to allow for adaptable profile shapes (i.e., to bend and flex such as shown in FIG. 1). As has been mentioned, this final display assembly may be very thin compared to, for example, a conventional display assembly constructed on a silicon substrate. For instance, the final display assembly may be between less than 10 microns in thickness (e.g., 5 microns, etc.), less than 100 microns in thickness, less than 500 microns in thickness, or the like.

In certain implementations, an integrated circuit such as integrated circuit 508 may be implemented as a backplane circuit that includes logical and electrical backplane circuitry for driving the entire set of pixel emitters included on a given display assembly. The example of display assembly 100 in FIG. 1 shows just one integrated circuit with this type of assumption, for example, as does the display assembly fabricated over the stages shown in FIGS. 5A-5K. While such a backplane circuit may be adequate in certain scenarios (e.g., scenarios where the backplane circuit may be relatively large and/or the number of pixel emitters on the display may be relatively small), however, implementing all the logical and electrical backplane circuitry on a unitary integrated circuit may be impractical or undesirable for other scenarios.

One reason for this that has been mentioned is that there is a finite amount of area on any given integrated circuit that can be dedicated for a communication interface to the various pixel emitters. For example, even if 500 fine-pitched traces per millimeter can reasonably be connected around a perimeter of a given integrated circuit, a display assembly featuring 10,000 or 100,000 or more pixel emitters may overwhelm this amount of space if the integrated circuit is as small as desired for the design. Accordingly, as has been mentioned and as will now be described in more detail, this fanout issue may be addressed by dividing the display into a plurality of display tiles, each including a respective subset of the overall set of pixel emitters, and employing some type of tiled architecture, a few examples of which will be described below.

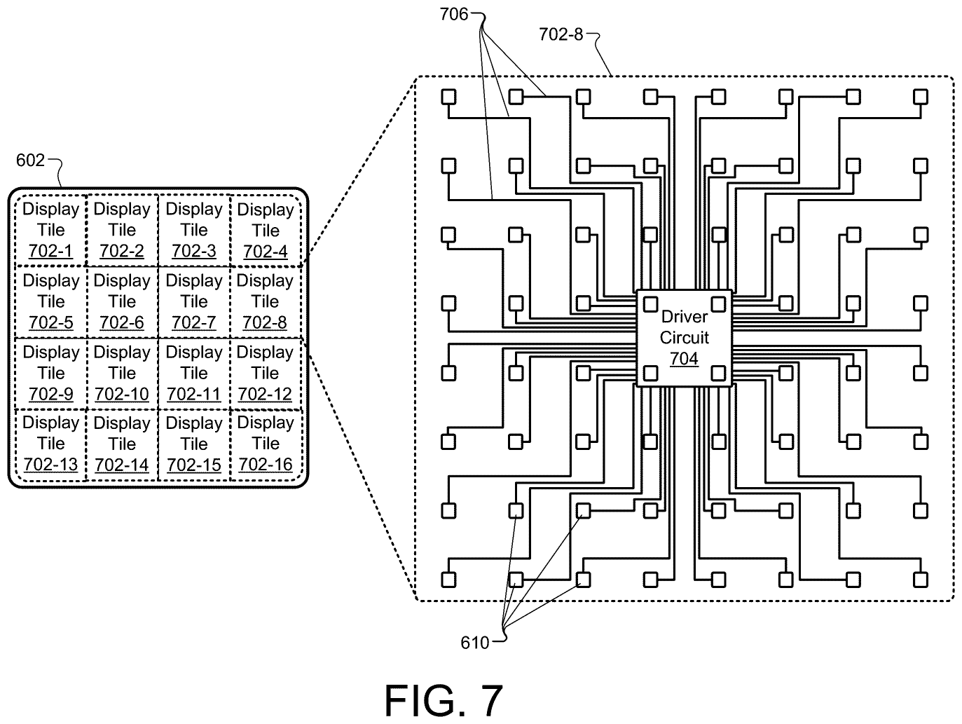

To illustrate, FIG. 7 shows illustrative display tiles that could be implemented within direct-view display 602 in accordance with principles described herein. More particularly, in this example, direct-view display 602 (described above in relation to FIG. 6) is shown to be divided into a 4×4 grid of 16 display tiles 702-1 through 702-16 (i.e., display tiles 702-1, 702-2, 702-3, 702-4, 702-5, 702-6, 702-7, 702-8, 702-9, 702-10, 702-11, 702-12, 702-13, 702-14, 702-15, and 702-16) that will each be understood to include a respective driver circuit (e.g., an integrated circuit such as integrated circuit 508) and a respective subset of pixel emitters (e.g., from all the set of pixel emitters 520 of the display assembly). For example, display tile 702-8 (selected arbitrarily) is shown, in a zoomed-in segment outlined by a dotted line in FIG. 7, to include a driver circuit 704 that is connected, by various electrical connections 706 (e.g., traces such as those described above to be formed from conductive material 504 and only a few of which are explicitly labeled), to a subset of the pixel emitters 610 (described above as being transferred to the display assembly) that are associated with display tile 702-8.

Respective driver circuits (similar to driver circuit 704 of display tile 702-8) and respective subsets of pixel emitters (similar to the subset of pixel emitters 610 of display tile 702-8) will be understood to be included within each of the display tiles 702-1 through 702-16. As with other integrated circuits described above, these driver circuits may be implemented by unpackaged semiconductor dies, fully-packaged chips, or other suitable types of integrated circuits (e.g., CMOS integrated circuits). Additionally, a controller circuit, which is not shown, and which may also be implemented as a CMOS integrated circuit, may be disposed somewhere within direct-view display 602 (e.g., within one of the display tiles or positioned on a boundary between two or more of the display tiles). All of these components (i.e., the pixel emitters, the driver circuits, the controller circuit, etc.) may be fabricated separately and then transferred to the display assembly implementing direct-view display 602 in the ways that have been described.

FIG. 7 shows direct-view display 602 to be divided into 16 square (or nearly square) display tiles and shows the example display tile 702-8 to include a subset of pixel emitters 610 in an 8×8 square grid including 64 pixel emitters. These numbers, shapes, and layout are provided only for the sake of illustration, and it will be understood that a given implementation of direct-view display 602 could include any suitable number of display tiles (more or less than the 16 shown in the example of FIG. 7), each with any suitable number of pixel emitters (more or less than the 64 shown in FIG. 7). Indeed, different implementations may handle a tradeoff between routing complexity and display thickness on the one hand (which may be optimized by having fewer portions and driver circuits for the controller circuit to be routed to) and power and chip complexity/cost on the other hand (which may be optimized by having more portions and driver circuits that are each responsible for fewer pixel emitters and thus use less power and buffering resources, etc.) in different ways according to their unique design goals.

Additionally, just as the corner display tiles of direct-view display 602 (i.e., display tiles 702-1, 702-4, 702-13, and 702-16) are shown to be non-square shapes (i.e., due to the rounded corners), it will be understood that the shape and lattice type of the pixel emitters in any given portion need not be square or rectilinear. For instance, as described and illustrated above, pixel emitters could be disposed on other types of lattices (e.g., a triangular lattice, a hexagonal lattice, etc.) or may be arranged in irregular ways that do not necessarily conform with any standard lattice type. Along with this flexibility in how pixel emitters may be arranged within a given display tile, display tiles themselves may be implemented in a variety of ways. For example, depending on certain characteristics of the display being constructed, display tiles could have different shapes and sizes, could be overlapping or non-overlapping, could arrange their driver circuits in different places with respect to their pixel emitters, and so forth.

The tiled architecture described in relation to FIG. 7 includes a single controller circuit controlling respective driver circuits for each display tile (e.g., including driver circuit 704 for display tile 702-8). These driver circuits may, themselves, be active integrated circuits and the various backplane roles may be divided up between the controller circuit and the driver circuits in a variety of ways. Indeed, for an even larger display, multiple layers of controller circuit hierarchy could be employed such that a master controller provides direction to one or more additional hierarchical control layers that ultimately control a large number of driver circuits that actually drive the various subsets of pixel emitters.

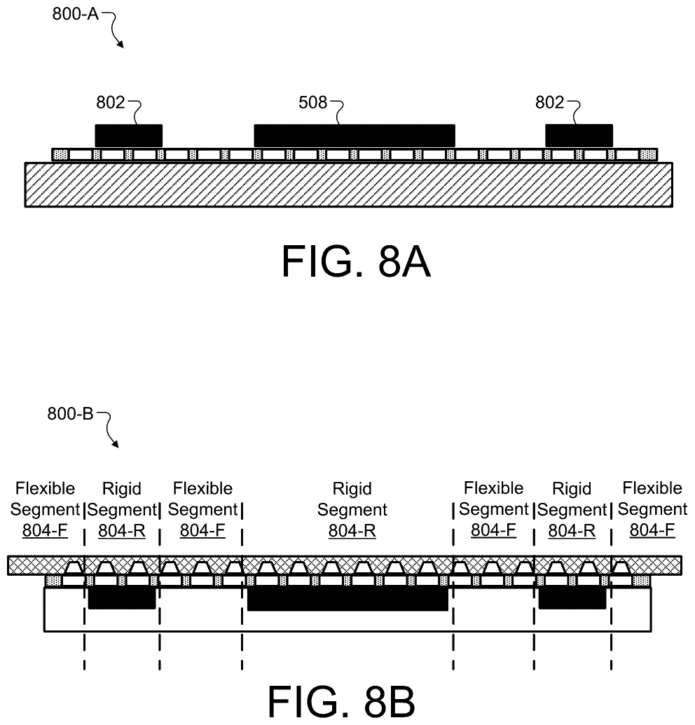

In other tiled architectures, passive interposer circuits could be used to support a backplane circuit that performs all the logical and electrical backplane functions but that is too small to handle the fanout to all the pixel emitters. In any of these or other architectures, there may also be components other than the additional integrated circuits (e.g., driver circuits, interposer circuits) that may be integrated within the display assembly. For example, sensors could be integrated with the circuitry in various ways to provide a variety of functions. A few specific examples of display assemblies with tiled architectures and additional components will now be described in relation to FIGS. 8A-8B, 9A-9B, and 10A-10B.

FIGS. 8A-8B show illustrative aspects of fabricating a shape-adaptive display assembly that includes additional integrated circuits in accordance with principles described herein. More particularly, FIG. 8A shows a stage 800-A based on stage 500-D described above in relation to FIG. 5D, while FIG. 8B shows a final stage 800-B based on the final stage 500-K described above in relation to FIG. 5K.

At stage 800-A, FIG. 8A shows that a plurality of additional integrated circuits 802 may be coupled, along with the integrated circuit 508 described above in relation to FIG. 5D, to the first side of the pattern of conductive material 504. However, whereas integrated circuit 508 is shown to be centralized in the middle of the display assembly, the plurality of additional integrated circuits 802 are shown to be distributed away from the center (e.g., to help with signal distribution fanout, as has been described).

At stage 800-B, FIG. 8B shows that the molding layer may be further configured to encapsulate the plurality of additional integrated circuits 802 (along with the integrated circuit 508), and that the other layers (e.g., the pixel emitters 520, the laminate layer 524, etc.) may all be implemented similarly as has been described. Just as integrated circuit 508 is illustrated as being included within a rigid segment 804-R, FIG. 8B shows that the smaller integrated circuits 802 are similarly included within their own rigid segments 804-R. This is because the additional integrated circuits 802 may, like the integrated circuit 508, be fabricated on a rigid substrate (e.g., a silicon substrate configured for fabricating CMOS circuitry). Other portions of the display assembly that do not have an integrated circuit, however, are shown to be flexible segments 804-F.

FIG. 8B shows rigid segments 804-R and flexible segments 804-F that are more closely aligned with the edges of the integrated circuits than illustrated above for the display assembly at final stage 500-K. In other words, as shown, the precise portions of the display assembly where the additional integrated circuits 802 are disposed may be similarly rigid as the portion corresponding to the rigid integrated circuit 508. It will be understood, however, that these additional integrated circuits 802 may be much smaller than integrated circuit 508 in certain examples, and, as such, the rigidity of the places where they are disposed may be of less importance or may even be relatively negligible. The scale of the various segments and the respective sizes of the integrated circuits are not necessarily drawn to scale in these figures, and it may be the case that the edges of the display assembly (e.g., portions corresponding to flexible segments 528-F in FIG. 5F) may be similarly flexible whether or not the small integrated circuits 802 are included. Alternatively, the segments where the additional integrated circuits 802 are disposed may, as shown, be rigid and configured to retain the planar profile shape, while segments between the integrated circuits may be flexible and used to curve around a corner or the like.

As described above in relation to FIG. 7, the display assembly shown at final stage 800-B could implement a tiled architecture in which a controller circuit communicates with a plurality of driver circuits, which, in turn, control (i.e., drive) respective subsets of pixel emitters. More particularly, in this example, the integrated circuit 508 may be implemented as the controller circuit and may include logical backplane circuitry for controlling the plurality of additional integrated circuits 802, while the plurality of additional integrated circuits 802 are implemented as driver circuits each including electrical backplane circuitry for driving a respective subset of the plurality of pixel emitters. As used herein, logical backplane circuitry may refer to circuitry for performing certain backplane functions such as, without limitation, image processing, data buffering, PWM sequencing, and so forth. Electrical backplane circuitry may then refer to circuitry (e.g., pixel driver circuitry) used to drive voltage or current to the various pixel emitters to cause them to emit light. While the electrical backplane circuitry may be implemented on the driver circuits in these examples, it will be understood that the logical backplane circuitry may be distributed between the controller circuit and the driver circuits in a variety of ways to achieve the aims and design objectives of a given implementation.

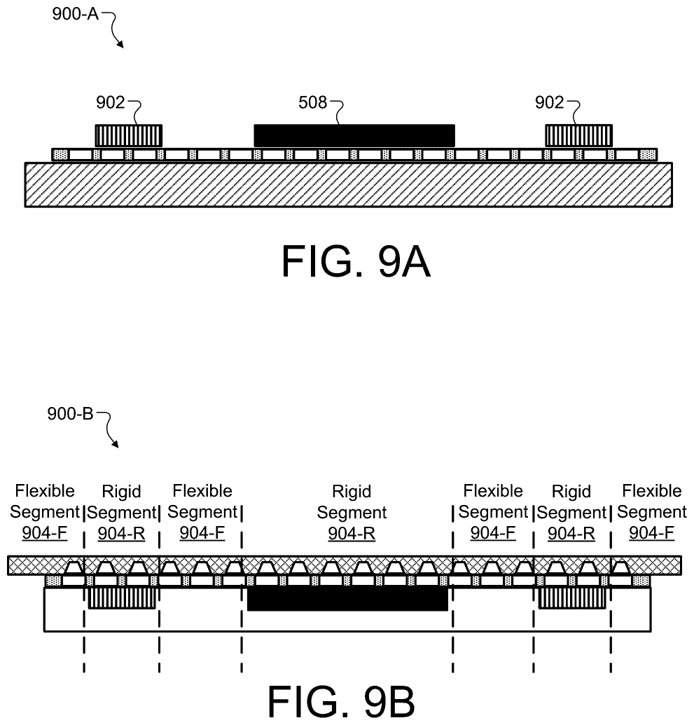

FIGS. 9A-9B show illustrative aspects of fabricating a shape-adaptive display assembly that includes passive interposer circuits in accordance with principles described herein. More particularly, FIG. 9A shows a stage 900-A based on stage 500-D described above in relation to FIG. 5D, while FIG. 9B shows a final stage 900-B based on the final stage 500-K described above in relation to FIG. 5K.

At stage 900-A, FIG. 9A shows that a plurality of passive interposer circuits 902 may be coupled, along with the integrated circuit 508 described above in relation to FIG. 5D, to the first side of the pattern of conductive material 504. However, whereas integrated circuit 508 is shown to be centralized in the middle of the display assembly, the plurality of passive interposer circuits 902 are shown to be distributed away from the center (e.g., to help with signal distribution fanout, as has been described).

At stage 900-B, FIG. 9B shows that the molding layer may be further configured to encapsulate the plurality of passive interposer circuits 902 (along with the integrated circuit 508), and that the other layers (e.g., the pixel emitters 520, the laminate layer 524, etc.) may all be implemented similarly as has been described. Just as integrated circuit 508 is illustrated as being included within a rigid segment 904-R, FIG. 9B shows that the smaller interposer circuits 902 are similarly included within their own rigid segments 904-R. This is because the passive interposer circuits 902 may, like the integrated circuit 508, be fabricated on a rigid substrate such as a silicon substrate. Other portions of the display assembly that do not have an integrated circuit, however, are shown to be flexible segments 904-F. Similar to FIG. 8B, FIG. 9B shows rigid segments 804-R and flexible segments 904-F that are more closely aligned with the edges of the rigid circuits 508 and 902 than illustrated above for the display assembly at final stage 500-K. It will again be understood, however, that these interposer circuits 902 may be smaller than integrated circuit 508, and, as such, their rigidity may be of less consequence than the rigidity of integrated circuit 508.

Similar to the tiled architecture described above in relation to FIG. 7, the display assembly shown at final stage 900-B could implement a tiled architecture in which a backplane circuit communicates with a plurality of passive interposer circuits, which, in turn, are electrically connected to respective subsets of pixel emitters. More particularly, in this example, the integrated circuit 508 may be implemented as a backplane circuit that includes all the logical and electrical backplane circuitry for driving the plurality of pixel emitters, while the plurality of passive interposer circuits 902 may each be electrically coupled to a respective subset of the plurality of pixel emitters to facilitate distribution of signaling from the backplane circuit to the plurality of pixel emitters. In other words, unlike the additional integrated circuits 802 described above, which may include active circuitry configured to perform electrical and logical backplane functions, the interposer circuits 902 may be passive and configured only to facilitate the signal distribution (leaving both logical and electrical backplane functions to the backplane circuit of integrated circuit 508 in this example).

In some examples, various sensors could be integrated with a standalone backplane circuit (such as the integrated circuit 508 in the example of FIGS. 5A-5K) or with a tiled architecture that includes either additional integrated circuits (such as the additional integrated circuits 802 in the example of FIGS. 8A-8B) or passive interposer circuits (such as the passive interposer circuits 902 in the example of FIGS. 9A-9B). For example, sensors used to detect user identity (e.g., fingerprint sensors, facial sensors, etc.) or to facilitate control of the device (e.g., touchscreen sensors, etc.) could be distributed across the display at various locations, including at locations where the sensors are integrated with other integrated circuits or interposer circuits.

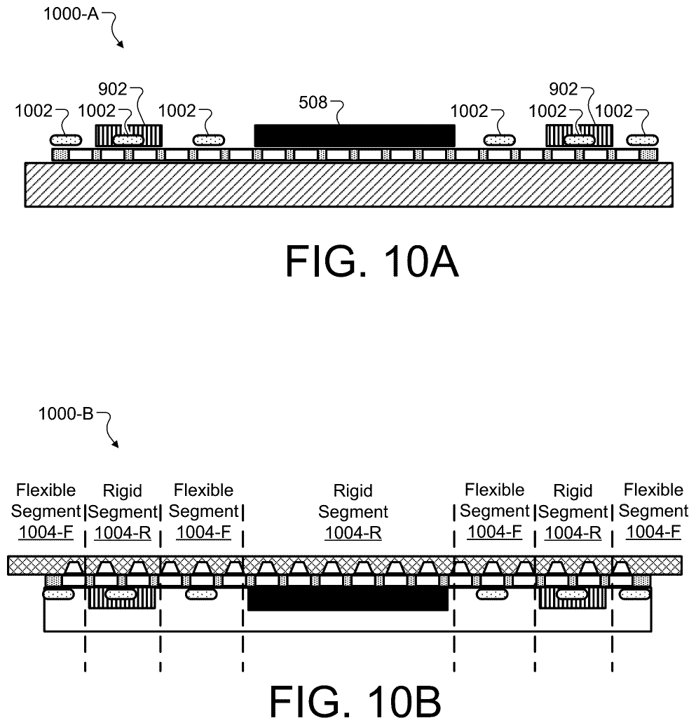

To illustrate, FIGS. 10A-10B show illustrative aspects of fabricating a shape-adaptive display assembly that integrates sensors in accordance with principles described herein. More particularly, FIG. 10A shows a stage 1000-A based on stage 900-A described above in relation to FIG. 9A, while FIG. 10B shows a final stage 1000-B based on final stage 1000-B described above in relation to FIG. 10B. It will be understood that sensors could similarly be integrated with a display assembly such as described in relation to FIGS. 8A-8B or FIGS. 5A-5K.

At stage 1000-A, FIG. 10A shows that the passive interposer circuits 902 described above may again be coupled, along with the integrated circuit 508, to the first side of the pattern of conductive material 504. Again, whereas integrated circuit 508 is shown to be centralized in the middle of the display assembly, the passive interposer circuits 902 are shown to be distributed away from the center (e.g., to help with signal distribution fanout, as has been described). Along with the passive interposer circuits 902, FIG. 10A also shows that sensors 1002 may be coupled to the first side of the pattern of conductive material in a similar way. At least some of these sensors 1002, as shown, may be disposed on flexible segments 1004-F, while others may be integrated with the circuits and disposed on rigid segments 1004-R.

At stage 1000-B, FIG. 10B shows that the molding layer may be further configured to encapsulate the plurality of sensors 1002 (along with the integrated circuit 508 and the passive interposer circuits 902), and that the other layers (e.g., the pixel emitters 520, the laminate layer 524, etc.) may all be implemented similarly as has been described.

For certain devices, applications, or use cases, it may be desirable to have a display assembly that is very large and/or that requires shape-adaptiveness to a more significant degree. At one extreme, for example, a display assembly may be desired that can adapt to a curved profile shape of a curved display where the curved profile shape extends 360 degrees to complete a full loop. For example, a cylindrical object could have a curved screen that goes all the way 360° around the cylinder.

Shape-adaptive display assemblies described herein could be used to implement this type of display in various ways. As one example, a singular display assembly such as described above could include a long flexible segment configured to extend 360° to wrap all the way around the loop. As another example, a display assembly such as described above could implement one portion of a plurality of portions included in a composite display assembly. In this example, the plurality of portions of the composite display assembly could be collectively configured to adapt to a curved profile shape of a curved display, including where the curved profile shape of the curved display extends 360° to complete the full loop, as has been described.

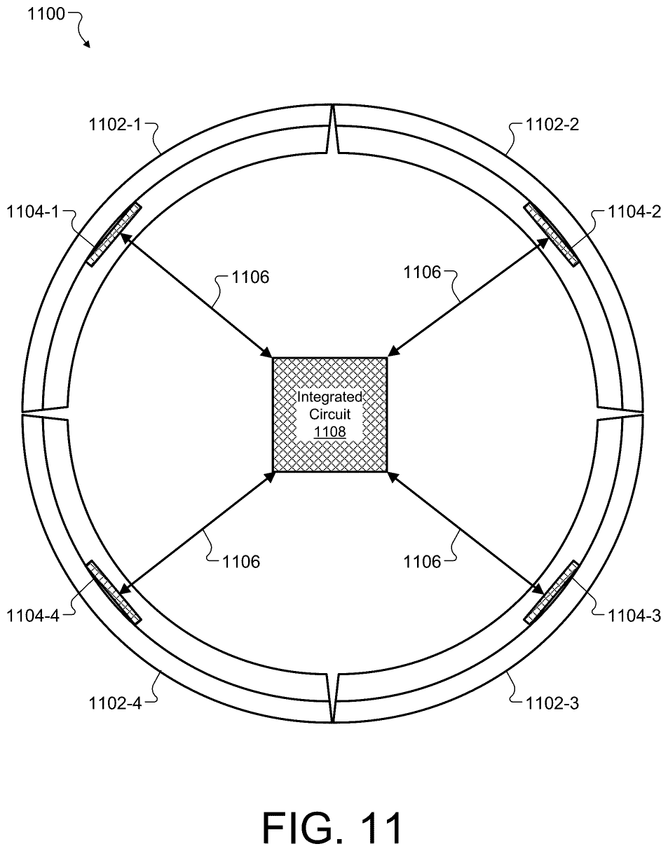

To illustrate this latter type of example, FIG. 11 shows illustrative aspects of a composite display assembly 1100 that includes a plurality of portions 1102-1, 1102-2, 1102-3, and 1102-4 that are each implemented as a shape-adaptive display assembly in accordance with principles described herein. As shown, for example, each of the portions 1102-1, 1102-2, 1102-3, and 1102-4 are shown to include a respective integrated circuit (i.e., an integrated circuit 1104-1 within portion 1102-1, an integrated circuit 1104-2 within portion 1102-2, an integrated circuit 1104-3 within portion 1102-3, and an integrated circuit 1104-4 within portion 1102-4), along with non-descript layers that will be understood to represent the same layers of pixel emitters, conductive material, dielectric material, molding material, laminate material, and so forth, as have been described.

The various portions of composite display assembly 1100 are shown to be in communication, by way of communication lines 1106 (e.g., ITO or copper signal lines, etc.), with an integrated circuit 1108 that may be integrated in the composite display assembly 1100 and configured to control each of the respective integrated circuits 1104-1 through 1104-4 in any suitable manner. As one example, integrated circuit 1108 could be implemented as a controller circuit and the integrated circuits 1104-1 through 1104-4 could be implemented as respective driver circuits. As another example, integrated circuits 1104-1 through 1104-4 could be implemented as respective controller circuits or backplane circuits (possibly in communication with additional integrated circuits and/or passive interposer circuits that are not explicitly shown) while integrated circuit 1108 could be a higher-level controller circuit that is above the other controller circuits in the hierarchy (using a multi-tier hierarchy such as described above).

Certain methods and processes described herein may be implemented at least in part as instructions embodied in a non-transitory computer-readable medium and executable by one or more computing devices. In general, a processor (e.g., a microprocessor) receives instructions, from a non-transitory computer-readable medium (e.g., a memory, etc.), and executes those instructions, thereby performing one or more operations such as the operations described herein. Such instructions may be stored and/or transmitted using any of a variety of known computer-readable media.

A computer-readable medium (also referred to as a processor-readable medium) includes any non-transitory medium that participates in providing data (e.g., instructions) that may be read by a computer (e.g., by a processor of a computer). Such a medium may take many forms, including, but not limited to, non-volatile media, and/or volatile media. Non-volatile media may include, for example, optical or magnetic disks and other persistent memory. Volatile media may include, for example, dynamic random-access memory (DRAM), which typically constitutes a main memory. Common forms of computer-readable media include, for example, a disk, hard disk, magnetic tape, any other magnetic medium, a compact disc read-only memory (CD-ROM), a digital video disc (DVD), any other optical medium, random access memory (RAM), programmable read-only memory (PROM), electrically erasable programmable read-only memory (EPROM), FLASH-EEPROM, any other memory chip or cartridge, or any other tangible medium from which a computer can read.

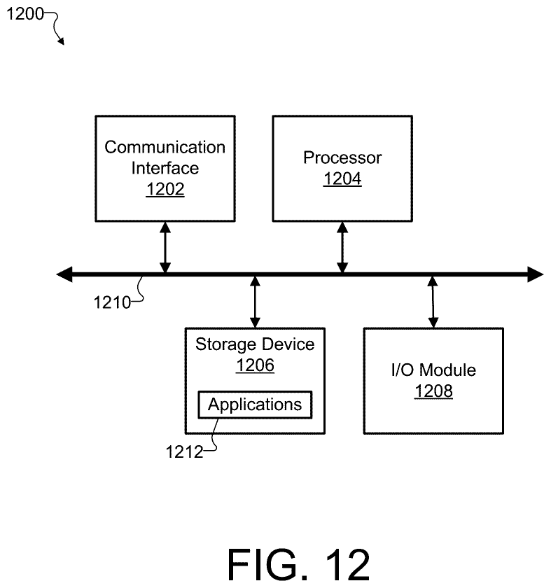

FIG. 12 shows an illustrative computing system 1200 that may be used to implement various devices and/or systems in accordance with principles described herein. For example, computing system 1200 may include or implement (or partially implement) display assemblies described herein, display fabrication systems, devices described herein to feature such as display assemblies (e.g., smartwatch devices, etc.), as well as any implementations thereof, any components thereof, and/or other devices used therewith.

As shown in FIG. 12, computing system 1200 may include a communication interface 1202, a processor 1204, a storage device 1206, and an input/output (I/O) module 1208 communicatively connected via a communication infrastructure 1210. While an illustrative computing system 1200 is shown in FIG. 12, the components illustrated in FIG. 12 are not intended to be limiting. Additional or alternative components may be used in other embodiments. Components of computing system 1200 shown in FIG. 12 will now be described in additional detail.

Communication interface 1202 may be configured to communicate with one or more computing devices. Examples of communication interface 1202 include, without limitation, a wired network interface (such as a network interface card), a wireless network interface (such as a wireless network interface card), a modem, an audio/video connection, and any other suitable interface.

Processor 1204 generally represents any type or form of processing unit capable of processing data or interpreting, executing, and/or directing execution of one or more of the instructions, processes, and/or operations described herein. Processor 1204 may direct execution of operations in accordance with one or more applications 1212 or other computer-executable instructions such as may be stored in storage device 1206 or another computer-readable medium.

Storage device 1206 may include one or more data storage media, devices, or configurations and may employ any type, form, and combination of data storage media and/or device. For example, storage device 1206 may include, but is not limited to, a hard drive, network drive, flash drive, magnetic disc, optical disc, RAM, dynamic RAM, other non-volatile and/or volatile data storage units, or a combination or sub-combination thereof. Electronic data, including data described herein, may be temporarily and/or permanently stored in storage device 1206. For example, data representative of one or more executable applications 1212 configured to direct processor 1204 to perform any of the operations described herein may be stored within storage device 1206. In some examples, data may be arranged in one or more databases residing within storage device 1206.

I/O module 1208 may include one or more I/O modules configured to receive user input and provide user output. One or more I/O modules may be used to receive input for a single virtual experience. I/O module 1208 may include any hardware, firmware, software, or combination thereof supportive of input and output capabilities. For example, I/O module 1208 may include hardware and/or software for capturing user input, including, but not limited to, a keyboard or keypad, a touchscreen component (e.g., touchscreen display), a receiver (e.g., an RF or infrared receiver), motion sensors, and/or one or more input buttons.

I/O module 1208 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O module 1208 is configured to provide graphical data to a display for presentation to a user. The graphical data may be representative of one or more graphical user interfaces and/or any other graphical content as may serve a particular implementation.

The following examples describe implementations of shape-adaptive display assemblies in accordance with principles described herein.

Example 1: A display assembly comprising: a rigid segment configured to maintain a planar profile shape and a flexible segment configured to allow for an adaptable profile shape; a pattern of conductive material extending over the rigid segment and the flexible segment; an integrated circuit disposed on the rigid segment without extending to the flexible segment, the integrated circuit coupled to a first side of the pattern of conductive material; a molding layer extending over the rigid segment and the flexible segment, the molding layer deposited on the first side of the pattern of conductive material and encapsulating the integrated circuit; and a plurality of pixel emitters coupled to a second side of the pattern of conductive material opposite the first side of the pattern of conductive material.

Example 2: The display assembly of any of the preceding examples, wherein: the plurality of pixel emitters is implemented by a set of micro light emitting diodes (microLEDs) transferred from a donor wafer on which the set of microLEDs is fabricated; the plurality of pixel emitters is fabricated at a first pitch on the donor wafer, the first pitch being smaller than a second pitch at which the plurality of pixel emitters is coupled to the pattern of conductive material; and the display assembly is configured for use as a smartwatch display.

Example 3: The display assembly of any of the preceding examples, further comprising a plurality of additional integrated circuits coupled to the first side of the pattern of conductive material, wherein: the molding layer is further configured to encapsulate the plurality of additional integrated circuits; the integrated circuit is implemented as a controller circuit that includes logical backplane circuitry for controlling the plurality of additional integrated circuits; and the plurality of additional integrated circuits are implemented as driver circuits each including electrical backplane circuitry for driving a respective subset of the plurality of pixel emitters.

Example 4: A device comprising: a memory storing instructions; a processor communicatively coupled to the memory and configured to execute the instructions to present image content; and a display assembly having a rigid segment with a planar profile shape and a flexible segment with a non-planar profile shape, the display assembly including: a pattern of conductive material extending over the rigid segment and the flexible segment; an integrated circuit disposed on the rigid segment without extending to the flexible segment, the integrated circuit coupled to a first side of the pattern of conductive material; a molding layer extending over the rigid segment and the flexible segment, the molding layer deposited on the first side of the pattern of conductive material and encapsulating the integrated circuit; and a plurality of pixel emitters coupled to a second side of the pattern of conductive material opposite the first side of the pattern of conductive material, the plurality of pixel emitters being configured to display the image content presented by the processor.

Example 5: The device of any of the preceding examples, implemented as a smartwatch device and wherein: the plurality of pixel emitters is implemented by a set of micro light emitting diodes (microLEDs) transferred from a donor wafer on which the set of microLEDs is fabricated; the plurality of pixel emitters is fabricated at a first pitch on the donor wafer, the first pitch being smaller than a second pitch at which the plurality of pixel emitters is coupled to the pattern of conductive material; and the display assembly is configured for use as a display of the smartwatch device.

Example 6: The device of any of the preceding examples, wherein: the display assembly further includes a plurality of additional integrated circuits coupled to the first side of the pattern of conductive material; the molding layer is further configured to encapsulate the plurality of additional integrated circuits; the integrated circuit is implemented as a controller circuit that includes logical backplane circuitry for controlling the plurality of additional integrated circuits; and the plurality of additional integrated circuits are implemented as driver circuits each including electrical backplane circuitry for driving a respective subset of the plurality of pixel emitters.

Example 7: A method for fabricating a display assembly having a rigid segment and a flexible segment, the method comprising: depositing a pattern of conductive material onto a first substrate; coupling an integrated circuit to a first side of the pattern of conductive material, the integrated circuit disposed on the rigid segment without extending to the flexible segment; depositing a molding layer onto the first side of the pattern of conductive material, the molding layer configured to encapsulate the integrated circuit and to extend over the rigid segment and the flexible segment; bonding a second substrate to the molding layer and removing the first substrate to expose a second side of the pattern of conductive material opposite the first side of the pattern of conductive material; and coupling a plurality of pixel emitters to the second side of the pattern of conductive material and removing the second substrate.

Example 8: The method of any of the preceding examples, wherein: the integrated circuit, the first substrate, and the second substrate are rigid; the conductive material and the molding layer are flexible; and when the display assembly is fabricated, the rigid segment is configured to maintain a planar profile shape and the flexible segment is configured to allow for an adaptable profile shape.

Example 9: The method of any of the preceding examples, wherein: the plurality of pixel emitters includes a first set of pixel emitters coupled to conductive material within the rigid segment and a second set of pixel emitters coupled to conductive material within the flexible segment; and the first set of pixel emitters is configured to display first content that is semantically distinct from second content that the second set of pixel emitters is configured to display.

Example 10: The method of any of the preceding examples, wherein: the coupling of the plurality of pixel emitters includes transferring the plurality of pixel emitters from a donor wafer on which the plurality of pixel emitters is fabricated; and the plurality of pixel emitters is fabricated at a first pitch on the donor wafer, the first pitch being smaller than a second pitch at which the plurality of pixel emitters is coupled to the pattern of conductive material.

Example 11: The method of any of the preceding examples, further comprising depositing, prior to coupling the integrated circuit to the first side of the pattern of conductive material, dielectric material over the pattern of conductive material.

Example 12: The method of any of the preceding examples, wherein the pattern of conductive material includes traces of a first conductive material connecting to pads of a second conductive material.

Example 13: The method of any of the preceding examples, wherein the first conductive material is an indium tin oxide (ITO) material and the second conductive material is either an ITO material or a copper material.

Example 14: The method of any of the preceding examples, wherein the molding layer is constructed of an organic material.

Example 15: The method of any of the preceding examples, further comprising depositing, subsequent to the coupling of the plurality of pixel emitters to the second side of the pattern of conductive material and prior to the removing of the second substrate, a laminate layer over the plurality of pixel emitters.

Example 16: The method of any of the preceding examples, wherein the integrated circuit is implemented as a backplane circuit that includes logical and electrical backplane circuitry for driving the plurality of pixel emitters.

Example 17: The method of any of the preceding examples, further comprising coupling a plurality of additional integrated circuits to the first side of the pattern of conductive material; wherein: the molding layer is further configured to encapsulate the plurality of additional integrated circuits, the integrated circuit is implemented as a controller circuit that includes logical backplane circuitry for controlling the plurality of additional integrated circuits, and the plurality of additional integrated circuits are implemented as driver circuits each including electrical backplane circuitry for driving a respective subset of the plurality of pixel emitters.

Example 18: The method of any of the preceding examples, further comprising coupling a plurality of passive interposer circuits to the first side of the pattern of conductive material; wherein: the molding layer is further configured to encapsulate the plurality of passive interposer circuits, the integrated circuit is implemented as a backplane circuit that includes logical and electrical backplane circuitry for driving the plurality of pixel emitters, and the plurality of passive interposer circuits are each electrically coupled to a respective subset of the plurality of pixel emitters to facilitate distribution of signaling from the integrated circuit to the plurality of pixel emitters.

Example 19: The method of any of the preceding examples, further comprising coupling a sensor to the first side of the pattern of conductive material, the sensor disposed on the flexible segment; wherein the molding layer is further configured to encapsulate the sensor.

Example 20: The method of any of the preceding examples, wherein: the display assembly implements one portion of a plurality of portions included in a composite display assembly; and the plurality of portions of the composite display assembly are collectively configured to adapt to a curved profile shape of a curved display.

Example 21: The method of any of the preceding examples, wherein the curved profile shape of the curved display extends 360 degrees to complete a full loop.

Example 22: The method of any of the preceding examples, wherein: the plurality of pixel emitters is implemented by a set of micro light emitting diodes (microLEDs); the integrated circuit is implemented by a complementary-metal-oxide-semiconductor (CMOS) integrated circuit; and the display assembly is configured for use as a smartwatch display.

Example 23: A display fabrication system comprising: a memory storing instructions; and a processor communicatively coupled to the memory and configured to execute the instructions to cause the display fabrication system to fabricate a display assembly by performing a process including: depositing a pattern of conductive material onto a first substrate; coupling an integrated circuit to a first side of the pattern of conductive material, the integrated circuit disposed on a rigid segment of the display assembly without extending to a flexible segment of the display assembly; depositing a molding layer onto the first side of the pattern of conductive material, the molding layer configured to encapsulate the integrated circuit and to extend over the rigid segment and the flexible segment; bonding a second substrate to the molding layer and removing the first substrate to expose a second side of the pattern of conductive material opposite the first side of the pattern of conductive material; and coupling a plurality of pixel emitters to the second side of the pattern of conductive material and removing the second substrate.

Example 24: The display fabrication system of any of the preceding examples, wherein: the integrated circuit, the first substrate, and the second substrate are rigid; the conductive material and the molding layer are flexible; and when the display assembly is fabricated, the rigid segment is configured to maintain a planar profile shape and the flexible segment is configured to allow for an adaptable profile shape.

Example 25: The display fabrication system of any of the preceding examples, wherein: the coupling of the plurality of pixel emitters includes transferring the plurality of pixel emitters from a donor wafer on which the plurality of pixel emitters is fabricated; and the plurality of pixel emitters is fabricated at a first pitch on the donor wafer, the first pitch being smaller than a second pitch at which the plurality of pixel emitters is coupled to the pattern of conductive material.

Various implementations of the systems and techniques described herein can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

A number of implementations have been described. Nevertheless, it will be understood that various modifications may be made without departing from the spirit and scope of the description and claims. In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

Specific structural and functional details disclosed herein are merely representative for purposes of describing example implementations. Example implementations, however, may be embodied in many alternate forms and should not be construed as limited to only the implementations set forth herein.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

The terminology used herein is for the purpose of describing particular implementations only and is not intended to be limiting of the implementations. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

Spatially relative terms, such as “beneath,” “below,” “lower,” “above,” “upper,” and the like, may be used herein for ease of description to describe one element or feature in relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 130 degrees or at other orientations) and the spatially relative descriptors used herein may be interpreted accordingly.

Unless otherwise defined, the terms (including technical and scientific terms) used herein have the same meaning as commonly understood by one of ordinary skill in the art to which these concepts belong. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Further to the descriptions above, a user may be provided with controls allowing the user to make an election as to both if and when systems, programs, or features described herein may enable collection of user information (e.g., information about a user's social network, social actions, or activities, profession, a user's preferences, or a user's current location), and if the user is sent content or communications from a server. In addition, certain data may be treated in one or more ways before it is stored or used, so that personally identifiable information is removed. For example, a user's identity may be treated so that no personally identifiable information can be determined for the user, or a user's geographic location may be generalized, or location information may be obtained (such as to a city, zip code, or state level), so that a particular location of a user cannot be determined. Thus, the user may have control over what information is collected about the user, how that information is used, and what information is provided to the user.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. A display assembly comprising:
a rigid segment configured to maintain a planar profile shape and a flexible segment configured to allow for an adaptable profile shape;
a pattern of conductive material extending over the rigid segment and the flexible segment;
an integrated circuit disposed on the rigid segment without extending to the flexible segment, the integrated circuit coupled to a first side of the pattern of conductive material;
a molding layer extending over the rigid segment and the flexible segment, the molding layer deposited on the first side of the pattern of conductive material and encapsulating the integrated circuit; and
a plurality of pixel emitters coupled to a second side of the pattern of conductive material opposite the first side of the pattern of conductive material.

2. The display assembly of claim 1, wherein:
the plurality of pixel emitters is implemented by a set of micro light emitting diodes (microLEDs) transferred from a donor wafer on which the set of microLEDs is fabricated;
the plurality of pixel emitters is fabricated at a first pitch on the donor wafer, the first pitch being smaller than a second pitch at which the plurality of pixel emitters is coupled to the pattern of conductive material; and
the display assembly is configured for use as a smartwatch display.

3. The display assembly of claim 1, further comprising a plurality of additional integrated circuits coupled to the first side of the pattern of conductive material, wherein:
the molding layer is further configured to encapsulate the plurality of additional integrated circuits;
the integrated circuit is implemented as a controller circuit that includes logical backplane circuitry for controlling the plurality of additional integrated circuits; and
the plurality of additional integrated circuits are implemented as driver circuits each including electrical backplane circuitry for driving a respective subset of the plurality of pixel emitters.

4. A device comprising:
a memory storing instructions;
a processor communicatively coupled to the memory and configured to execute the instructions to present image content; and
a display assembly having a rigid segment with a planar profile shape and a flexible segment with a non-planar profile shape, the display assembly including:
a pattern of conductive material extending over the rigid segment and the flexible segment;
an integrated circuit disposed on the rigid segment without extending to the flexible segment, the integrated circuit coupled to a first side of the pattern of conductive material;
a molding layer extending over the rigid segment and the flexible segment, the molding layer deposited on the first side of the pattern of conductive material and encapsulating the integrated circuit; and
a plurality of pixel emitters coupled to a second side of the pattern of conductive material opposite the first side of the pattern of conductive material, the plurality of pixel emitters being configured to display the image content presented by the processor.

5. The device of claim 4, implemented as a smartwatch device and wherein:
the plurality of pixel emitters is implemented by a set of micro light emitting diodes (microLEDs) transferred from a donor wafer on which the set of microLEDs is fabricated;
the plurality of pixel emitters is fabricated at a first pitch on the donor wafer, the first pitch being smaller than a second pitch at which the plurality of pixel emitters is coupled to the pattern of conductive material; and
the display assembly is configured for use as a display of the smartwatch device.

6. The device of claim 4, wherein:
the display assembly further includes a plurality of additional integrated circuits coupled to the first side of the pattern of conductive material;
the molding layer is further configured to encapsulate the plurality of additional integrated circuits;
the integrated circuit is implemented as a controller circuit that includes logical backplane circuitry for controlling the plurality of additional integrated circuits; and
the plurality of additional integrated circuits are implemented as driver circuits each including electrical backplane circuitry for driving a respective subset of the plurality of pixel emitters.

7. A method for fabricating a display assembly having a rigid segment and a flexible segment, the method comprising:
depositing a pattern of conductive material onto a first substrate;
coupling an integrated circuit to a first side of the pattern of conductive material, the integrated circuit disposed on the rigid segment without extending to the flexible segment;
depositing a molding layer onto the first side of the pattern of conductive material, the molding layer configured to encapsulate the integrated circuit and to extend over the rigid segment and the flexible segment;
bonding a second substrate to the molding layer and removing the first substrate to expose a second side of the pattern of conductive material opposite the first side of the pattern of conductive material; and
coupling a plurality of pixel emitters to the second side of the pattern of conductive material and removing the second substrate.

8. The method of claim 7, wherein:
the integrated circuit, the first substrate, and the second substrate are rigid;
the conductive material and the molding layer are flexible; and
when the display assembly is fabricated, the rigid segment is configured to maintain a planar profile shape and the flexible segment is configured to allow for an adaptable profile shape.

9. The method of claim 7, wherein:
the plurality of pixel emitters includes a first set of pixel emitters coupled to conductive material within the rigid segment and a second set of pixel emitters coupled to conductive material within the flexible segment; and
the first set of pixel emitters is configured to display first content that is semantically distinct from second content that the second set of pixel emitters is configured to display.

10. The method of claim 7, wherein:
the coupling of the plurality of pixel emitters includes transferring the plurality of pixel emitters from a donor wafer on which the plurality of pixel emitters is fabricated; and
the plurality of pixel emitters is fabricated at a first pitch on the donor wafer, the first pitch being smaller than a second pitch at which the plurality of pixel emitters is coupled to the pattern of conductive material.

11. The method of claim 7, further comprising depositing, prior to coupling the integrated circuit to the first side of the pattern of conductive material, dielectric material over the pattern of conductive material.

12. The method of claim 7, wherein the pattern of conductive material includes traces of a first conductive material connecting to pads of a second conductive material.

13. The method of claim 12, wherein the first conductive material is an indium tin oxide (ITO) material and the second conductive material is either an ITO material or a copper material.

14. The method of claim 7, wherein the molding layer is constructed of an organic material.

15. The method of claim 7, further comprising depositing, subsequent to the coupling of the plurality of pixel emitters to the second side of the pattern of conductive material and prior to the removing of the second substrate, a laminate layer over the plurality of pixel emitters.

16. The method of claim 7, wherein the integrated circuit is implemented as a backplane circuit that includes logical and electrical backplane circuitry for driving the plurality of pixel emitters.

17. The method of claim 7, further comprising coupling a plurality of additional integrated circuits to the first side of the pattern of conductive material;
wherein:
the molding layer is further configured to encapsulate the plurality of additional integrated circuits,
the integrated circuit is implemented as a controller circuit that includes logical backplane circuitry for controlling the plurality of additional integrated circuits, and
the plurality of additional integrated circuits are implemented as driver circuits each including electrical backplane circuitry for driving a respective subset of the plurality of pixel emitters.

18. The method of claim 7, further comprising coupling a plurality of passive interposer circuits to the first side of the pattern of conductive material;
wherein:
the molding layer is further configured to encapsulate the plurality of passive interposer circuits,
the integrated circuit is implemented as a backplane circuit that includes logical and electrical backplane circuitry for driving the plurality of pixel emitters, and
the plurality of passive interposer circuits are each electrically coupled to a respective subset of the plurality of pixel emitters to facilitate distribution of signaling from the integrated circuit to the plurality of pixel emitters.

19. The method of claim 7, further comprising coupling a sensor to the first side of the pattern of conductive material, the sensor disposed on the flexible segment;
wherein the molding layer is further configured to encapsulate the sensor.

20. The method of claim 7, wherein:
the display assembly implements one portion of a plurality of portions included in a composite display assembly; and
the plurality of portions of the composite display assembly are collectively configured to adapt to a curved profile shape of a curved display.

21. The method of claim 20, wherein the curved profile shape of the curved display extends 360 degrees to complete a full loop.

22. The method of claim 7, wherein:
the plurality of pixel emitters is implemented by a set of micro light emitting diodes (microLEDs);
the integrated circuit is implemented by a complementary-metal-oxide-semiconductor (CMOS) integrated circuit; and
the display assembly is configured for use as a smartwatch display.

23. A display fabrication system comprising:
a memory storing instructions; and
a processor communicatively coupled to the memory and configured to execute the instructions to cause the display fabrication system to fabricate a display assembly by performing a process including:
depositing a pattern of conductive material onto a first substrate;
coupling an integrated circuit to a first side of the pattern of conductive material, the integrated circuit disposed on a rigid segment of the display assembly without extending to a flexible segment of the display assembly;
depositing a molding layer onto the first side of the pattern of conductive material, the molding layer configured to encapsulate the integrated circuit and to extend over the rigid segment and the flexible segment;
bonding a second substrate to the molding layer and removing the first substrate to expose a second side of the pattern of conductive material opposite the first side of the pattern of conductive material; and
coupling a plurality of pixel emitters to the second side of the pattern of conductive material and removing the second substrate.

24. The display fabrication system of claim 23, wherein:
the integrated circuit, the first substrate, and the second substrate are rigid;
the conductive material and the molding layer are flexible; and
when the display assembly is fabricated, the rigid segment is configured to maintain a planar profile shape and the flexible segment is configured to allow for an adaptable profile shape.

25. The display fabrication system of claim 23, wherein:
the coupling of the plurality of pixel emitters includes transferring the plurality of pixel emitters from a donor wafer on which the plurality of pixel emitters is fabricated; and
the plurality of pixel emitters is fabricated at a first pitch on the donor wafer, the first pitch being smaller than a second pitch at which the plurality of pixel emitters is coupled to the pattern of conductive material.
